(19) United States
(12) Patent Application Publication
(10) Pub. No.: US 2023/0320058 A1
(43) Pub. Date: Oct. 5, 2023

(54) CO-OPTIMIZATION OF MEMORY AND LOGIC DEVICES BY SOURCE/DRAIN MODULATION AND STRUCTURES THEREOF

(71) Applicant: Taiwan Semiconductor Manufacturing Company, Ltd., Hsinchu (TW)

(72) Inventors: Ta-Chun Lin, Hsinchu (TW); Chih-Hung Hsieh, Hsin-Chu (TW); Chun-Jun Lin, Hsinchu City (TW); Kuo-Hua Pan, Hsinchu City (TW); Jhon Jhy Liaw, Hsinchu County (TW)

(21) Appl. No.: 17/870,341

(22) Filed: Jul. 21, 2022

Related U.S. Application Data
(60) Provisional application No. 63/362,498, filed on Apr. 5, 2022.

(51) Int. Cl. H01L 27/11

(52) U.S. Cl. CPC H01L 27/1104; H01L 27/1116

(57) ABSTRACT

Methods and structures for the co-optimization of memory and logic devices. A device includes a substrate having a first region and a second region. The device may include a first gate structure disposed in the first region and a second gate structure disposed in the second region. The device may further include a first source/drain feature disposed adjacent to the first gate structure and a second source/drain feature disposed adjacent to the second gate structure. A first top surface of the first source/drain feature and a second top surface of the second source/drain feature are substantially level. A first bottom surface of the first source/drain feature is a first distance away from the first top surface, and a second bottom surface of the second source/drain feature is a second distance away from the second top surface. In some cases, the second distance is greater than the first distance.

### CROSS-REFERENCE TO RELATED APPLICATION

This application claims the benefit of U.S. Provisional Application No. 63/362,498, filed Apr. 5, 2022, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). FinFETs have been used in a variety of applications, for example, to implement system-on-a-chip (SOC) logic devices and memory devices such as static random-access memory (SRAM), among others. Generally, SOC logic devices and SRAM devices have different design and performance requirements. For instance, as compared to SOC logic devices, SRAM devices require tighter control of short-channel effects (SCEs) (e.g., for Vmin improvement). However, while being necessary to meet power, performance, area, and cost (PPAC) scaling requirements, simultaneous optimization (co-optimization) of the performance and/or design requirements of SOC logic devices and SRAM devices has been challenging. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabricating a semiconductor device 300 according to one or more aspects of the present disclosure;

FIGS. 3A, 3B, 4A, 4B, 5A, 5B, 6A, 6B, 7A, 7B, 8A, 8B, 9A, and 9B provide cross-sectional views of embodiments of the semiconductor device 300 at various stages of processing according to the method of FIG. 2, along a plane substantially parallel to a plane defined by section AA′ of FIG. 1, according to one or more aspects of the present disclosure;

FIGS. 10A and 10B provide cross-sectional views of embodiments of the semiconductor device 300 along a plane substantially parallel to a plane defined by section BB′ of FIG. 1, in accordance with some embodiments;

FIG. 11 is a flow chart of a method of fabricating a semiconductor device 1200 according to one or more aspects of the present disclosure;

FIGS. 12A, 12B, 13A, 13B, 14A, 14B, 15A, 15B, 16A, 16B, 17A, and 17B provide cross-sectional views of embodiments of the semiconductor device 1200 at various stages of processing according to the method of FIG. 11, along a plane substantially parallel to a plane defined by section AA′ of FIG. 1, according to one or more aspects of the present disclosure;

FIG. 18 is a flow chart of an alternative method of fabricating the semiconductor device 1200 according to one or more aspects of the present disclosure;

FIGS. 19A and 19B provide cross-sectional views of embodiments of the semiconductor device 1200 during an ion implantation process according to the method of FIG. 18, along a plane substantially parallel to a plane defined by section AA′ of FIG. 1, according to one or more aspects of the present disclosure;

FIGS. 20, 21, 22, 23, and 24 provide cross-sectional views of other embodiments of the semiconductor device 1200 at various stages of processing according to the method of FIG. 11, along a plane substantially parallel to a plane defined by section AA′ of FIG. 1, according to one or more aspects of the present disclosure;

FIG. 25 is a flow chart of another method of fabricating the semiconductor device 1200 according to one or more aspects of the present disclosure;

FIGS. 26A and 26B provide cross-sectional views of embodiments of the semiconductor device 1200 during an ion implantation process according to the method of FIG. 25, along a plane substantially parallel to a plane defined by section AA′ of FIG. 1, according to one or more aspects of the present disclosure;

FIG. 27 illustrates a top-down view of a substrate region of the semiconductor device 1200 including SRAM cells after formation of a patterned mask layer, in accordance with some embodiments;

FIGS. 28A and 28B illustrate an embodiment of a final structure of the device 1200 fabricated according to the method of FIG. 25, according to one or more aspects of the present disclosure;

FIG. 29 is a flow chart of still another method of fabricating the semiconductor device 1200 according to one or more aspects of the present disclosure;

FIGS. 30A, 30B, and 30C provide cross-sectional views of embodiments of the semiconductor device 1200 during an ion implantation process according to the method of FIG. 29, along a plane substantially parallel to a plane defined by section AA′ of FIG. 1, according to one or more aspects of the present disclosure;

FIGS. 31A, 31B, and 31C illustrate top-down views of substrate regions which include an SRAM-HD cell, an SRAM-HC cell, and an SOC logic cell after formation of a patterned mask layer, in accordance with some embodiments;

FIGS. 32A, 32B, and 32C illustrate an embodiment of a final structure of the device 1200 fabricated according to the method of FIG. 29, according to one or more aspects of the present disclosure;

FIG. 33 is a flow chart of an alternative method of fabricating the semiconductor device 1200 according to one or more aspects of the present disclosure;

FIGS. 34A and 34B provide cross-sectional views of embodiments of the semiconductor device 1200 during an ion implantation process according to the method of FIG. 33, along a plane substantially parallel to a plane defined by section AA′ of FIG. 1, according to one or more aspects of the present disclosure;

FIGS. 35A and 35B illustrate top-down views of substrate regions which include a multi-port SRAM HC cell and an SOC logic cell after formation of a patterned mask layer, in accordance with some embodiments; and

FIGS. 36A and 36B illustrate an embodiment of a final structure of the device 1200 fabricated according to the method of FIG. 33, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm. Additionally, in some embodiments, the term “source/drain region(s)” may refer to a source or a drain, individually or collectively dependent upon the context.

It is also noted that the present disclosure presents embodiments in the form of multi-gate transistors or fin-type multi-gate transistors referred to herein as FinFET devices. Such a device may include a P-type metal-oxide-semiconductor FinFET device or an N-type metal-oxide-semiconductor FinFET device. The FinFET device may be a dual-gate device, tri-gate device, bulk device, silicon-on-insulator (SOI) device, and/or other configuration. One of ordinary skill may recognize other embodiments of semiconductor devices that may benefit from aspects of the present disclosure. For example, some embodiments as described herein may also be applied to gate-all-around (GAA) devices, Omega-gate (Ω-gate) devices, or Pi-gate (π-gate) devices.

The present disclosure is generally related to semiconductor devices and methods of forming the same. In particular, embodiments of the present disclosure provide a process and/or structure for co-optimization of system-on-a-chip (SOC) logic devices and static random-access memory (SRAM) devices to meet power, performance, area, and cost (PPAC) scaling requirements. In some examples, such co-optimization may be achieved by controlling respective source/drain (S/D) depths for each of the SOC logic devices and SRAM devices, as described in more detail below.

FinFETs have been used in a variety of applications, for example, to implement SOC logic devices and memory devices such as SRAM devices, among others. In at least some existing embodiments, FinFETs used to make SOC logic devices and SRAM devices may have substantially the same contacted poly pitch (CPP) and a similar fin critical dimension (CD). As a result, SOC logic devices and SRAM devices may have comparable source/drain (S/D) depths (e.g., S/D junction depths). However, each of these device types have different design and performance requirements. For instance, as compared to SOC logic devices, SRAM devices require tighter control of short-channel effects (SCEs) (e.g., for Vmin improvement). Thus, while being necessary to meet power, performance, area, and cost (PPAC) scaling requirements, simultaneous optimization (co-optimization) of the performance and/or design requirements of SOC logic devices and SRAM devices has been challenging. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods for the co-optimization of SOC logic devices and SRAM devices. In various embodiments, a semiconductor device may include individual device structures to simultaneously meet the performance and design requirements of each of the SOC logic devices and SRAM devices. As an example, and in accordance with the disclosed embodiments, intentionally different source/drain depths for logic devices (e.g., SOC logic devices) and SRAM devices are provided. In some embodiments, the source/drain depth for SRAM devices may be shallower than the source/drain depth for SOC logic devices, for example, to provide tighter control of SCEs.

In some embodiments, formation of the intentionally different source/drain depths may be accomplished by (i) a 2-step or multi-step S/D recess process using a high-grade photomask (e.g., such as EUV), or by (ii) an implantation-enhanced S/D recess process using at least one low-grade photomask. The implantation-enhanced S/D recess process may be accomplished at a reduced cost using simplified lithography, for example, as compared to the 2-step or multi-step S/D recess process. After the S/D recess process, an epitaxial S/D growth process is performed (e.g., in N-type and P-type regions of both SOC logic devices and SRAM devices) to form respective epitaxial S/D features having different source/drain depths. It is also noted that in various embodiments, the epitaxial S/D features are formed such that a top surface of the epitaxial S/D features is higher than a top surface of a corresponding fin structure to ensure full contact between the epitaxial S/D features and device channels formed within the fin structure. In general, embodiments disclosed herein provide device co-optimization for power, performance, area, cost (PPAC) metrics, circuit optimization by application-aware source/drain design, and possible cost reduction (e.g., using the implantation-enhanced S/D recess process). Regardless of the approach used, embodiments of the present disclosure provide independent optimization of S/D depth for N-type and P-type SOC logic device and SRAM devices. Additional embodiments and advantages are discussed below and/or will be evident to those skilled in the art in possession of this disclosure.

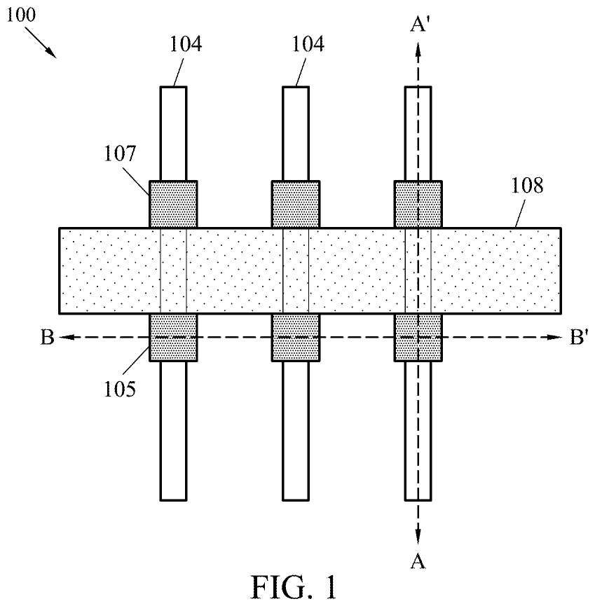

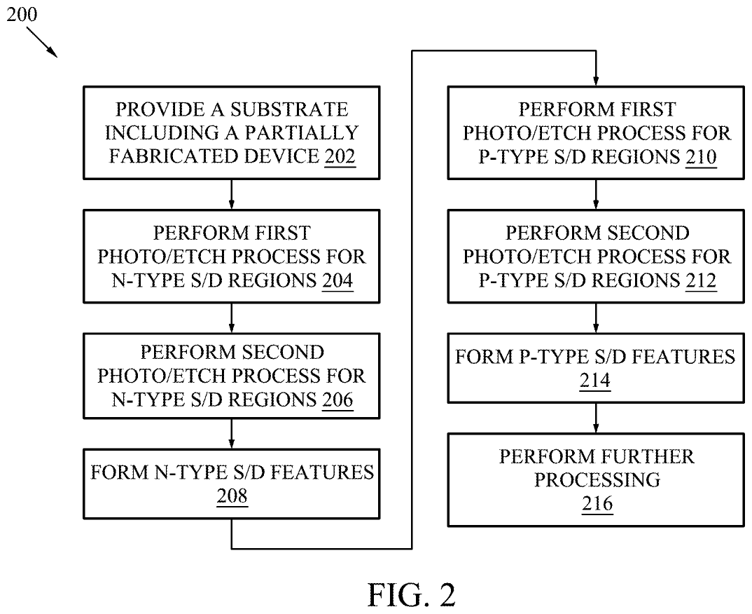

For purposes of the discussion that follows, FIG. 1 provides a simplified top-down layout view of a multi-gate device 100. In various embodiments, the multi-gate device 100 may include a FinFET device, a GAA transistor, or other type of multi-gate device. The multi-gate device 100 may include a plurality of fins 104 extending from a substrate, a gate structure 108 disposed over and around the fins 104, and source/drain regions 105, 107, where the source/drain regions 105, 107 are formed in, on, and/or surrounding the fins 104. As used herein, a source/drain region, or “s/d region,” may refer to a source or a drain of a device. It may also refer to a region that provides a source and/or drain for multiple devices. Thus, in the present example, it will be understood that the source/drain regions 105/107 may be interchangeably configured as the source region or the drain region of the multi-gate device 100. A channel region of the multi-gate device 100, which may include a plurality of semiconductor channel layers (e.g., when the multi-gate device 100 includes a GAA transistor), is disposed within the fins 104, underlying the gate structure 108, along a plane substantially parallel to a plane defined by section AA′ of FIG. 1. In some embodiments, sidewall spacers may also be formed on sidewalls of the gate structure 108. It is also noted that while the discussion that follows is directed to fabrication of FinFET devices, it will be understood that other types of devices (e.g., such as planar FETs, GAA FETs, or other suitable devices) may benefit from one or more of the embodiments described herein. Various other features of the multi-gate device 100 are discussed in more detail below with reference to the method of FIGS. 2, 11, 18, 25, 29, and 33.

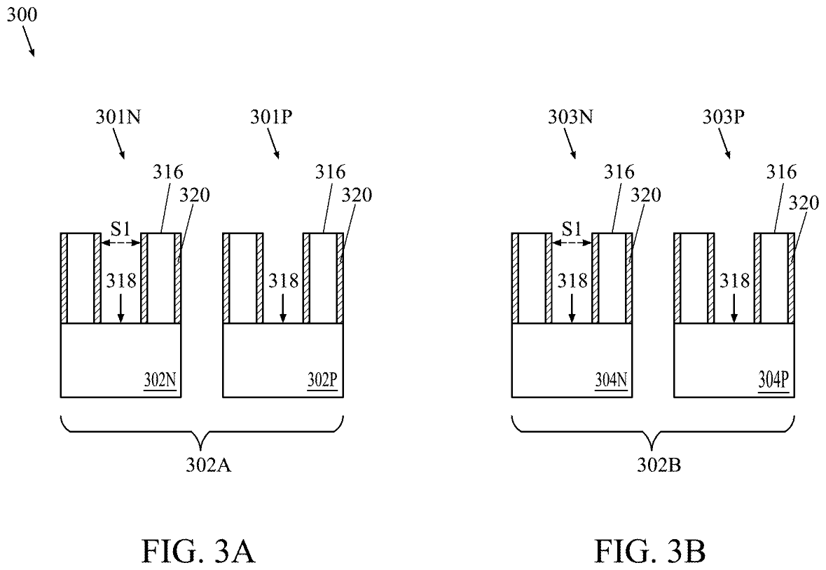

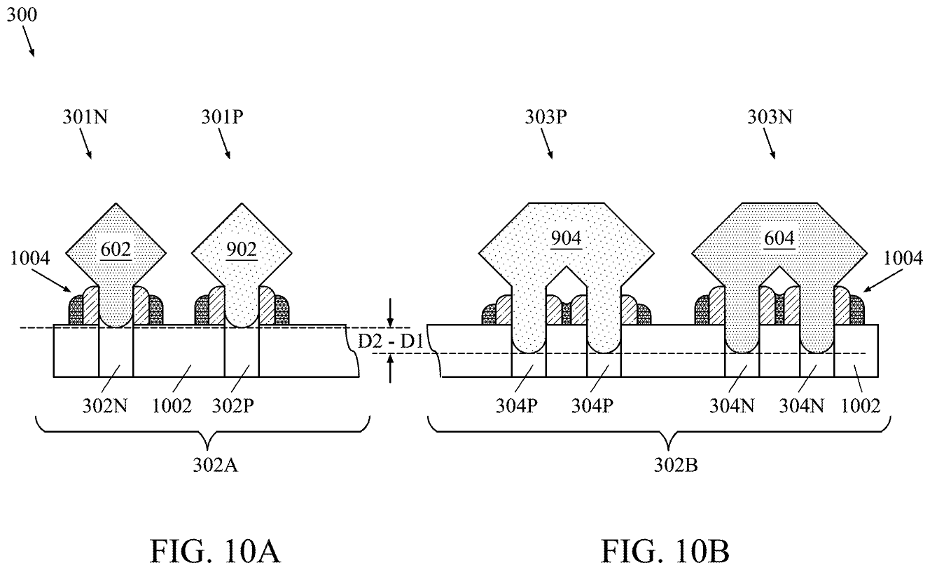

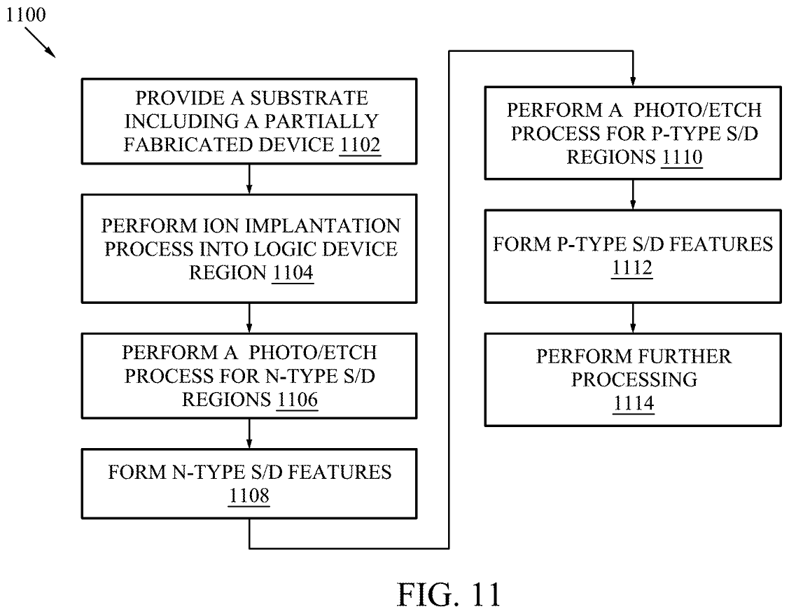

Referring to FIG. 2, illustrated therein is a method 200 of semiconductor fabrication including fabrication of a semiconductor device 300 having various device types (e.g., such as an SOC logic devices and SRAM devices) formed on a given substrate and that are co-optimized, for example by controlling S/D depth, in accordance with various embodiments. Embodiments of the method 200 are described below with reference to FIGS. 3A/3B-9A/9B, which provide cross-sectional views of embodiments of the device 300 along a plane substantially parallel to a plane defined by section AA′ of FIG. 1, and with reference to FIGS. 10A/10B, which provide cross-sectional views of embodiments of the device 300 along a plane substantially parallel to a plane defined by section BB′ of FIG. 1. In some embodiments, the co-optimization described with respect to the method 200 may be performed using a 2-step or multi-step S/D recess process for each of an N-type S/D and a P-type S/D for the various device types (e.g., the SOC logic devices and SRAM devices). However, other approaches, such as implantation-enhanced S/D recess processes are possible, as discussed below with reference to the methods of FIGS. 11, 18, 25, 29, and 33. The methods of FIGS. 2, 11, 18, 25, 29, and 33 are discussed below with reference to fabrication of FinFET devices. However, it will be understood that aspects of these methods may be equally applied to other types of devices such as planar FETs, GAA devices, other suitable devices, or other types of devices implemented using such devices, without departing from the scope of the present disclosure. In some embodiments, the methods of FIGS. 2, 11, 18, 25, 29, and 33 may be used to fabricate the multi-gate device 100, described above with reference to FIG. 1. Thus, one or more aspects discussed above with reference to the multi-gate device 100 may also apply to the methods of FIGS. 2, 11, 18, 25, 29, and 33. It is also understood that the methods of FIGS. 2, 11, 18, 25, 29, and 33 include steps having features of a complementary metal-oxide-semiconductor (CMOS) technology process flow and thus, are only described briefly herein. Also, additional steps may be performed before, after, and/or during the methods of FIGS. 2, 11, 18, 25, 29, and 33.

It is noted that certain aspects of the methods of FIGS. 2, 11, 18, 25, 29, and 33 are described as being performed in a particular region of a semiconductor device including a particular device type (e.g., such as a P-type SOC logic device, an N-type SOC logic device, a P-type SRAM device, an N-type SRAM device, or other device types). However, if not described as being performed in a region including a particular device type, the step of the methods of FIGS. 2, 11, 18, 25, 29, and 33 being described may be assumed as being performed across a plurality of regions including a plurality of device types (e.g., across a plurality of device type regions). Further, the semiconductor devices formed in accordance with the methods of FIGS. 2, 11, 18, 25, 29, and 33 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor devices described herein may include a plurality of semiconductor devices (e.g., transistors) which may be interconnected. Moreover, it is noted that the process steps of the methods of FIGS. 2, 11, 18, 25, 29, and 33, including any descriptions given with reference to the figures are merely exemplary and are not intended to be limiting beyond what is specifically recited in the claims that follow.

The method 200 begins at block 202 where a substrate including a partially fabricated device is provided. Referring to the example of FIGS. 3A, 3B, in an embodiment of block 202, partially fabricated N-type and P-type SRAM devices 301N, 301P are provided in a region 302A of a substrate, and partially fabricated N-type and P-type SOC logic devices 303N, 303P are provided in a region 302B of the substrate. In some embodiments, each of the N-type and P-type devices in each of the regions 302A, 302B may include a multi-gate device (e.g., such as a FinFET device), similar to the multi-gate device 100, discussed above. As such, FIGS. 3A, 3B provide cross-sectional views of embodiments of the N-type and P-type SRAM devices 301N, 301P, and the N-type and P-type SOC logic devices 303N, 303P along a plane substantially parallel to a plane defined by section AA′ of FIG. 1 (e.g., along the direction of the fins 104).

Each of the N-type and P-type SRAM devices 301N, 301P, and the N-type and P-type SOC logic devices 303N, 303P may be formed within different regions 302A, 302B of the same substrate, such as a silicon substrate. In some cases, the substrate may include various layers, including conductive or insulating layers formed on a semiconductor substrate. The substrate may include various doping configurations depending on design requirements as is known in the art. The substrate may also include other semiconductors such as germanium, silicon carbide (SiC), silicon germanium (SiGe), or diamond. Alternatively, the substrate may include a compound semiconductor and/or an alloy semiconductor. Further, the substrate may optionally include an epitaxial layer (epi-layer), may be strained for performance enhancement, may include a silicon-on-insulator (SOI) structure, and/or have other suitable enhancement features.

As shown in FIGS. 3A, 3B, the N-type and P-type SRAM devices 301N, 301P include fins 302N, 302P which extend from the underlying substrate in the region 302A, and the N-type and P-type SOC logic devices 303N, 303P include fins 304N, 304P which extend from the underlying substrate in the region 302B. The fins formed in each of the regions 302A, 302B may be similar to the fins 104, discussed above. In various embodiments, the fins 302N, 302P, 304N, 304P may be formed of the same material or a different material as the underlying substrate from which they extend. In at least some embodiments, the material used for the N-type fins 302N, 304N may include silicon, and the material used for the P-type fins 302P, 304P may include silicon or silicon germanium. In addition, shallow trench isolation (STI) features may also be formed to isolate each of the fins 302N, 302P, 304N, 304P from neighboring fins.

In some embodiments, the number of fins used to form each of the N-type and P-type SRAM devices 301N, 301P, and the N-type and P-type SOC logic devices 303N, 303P, within each of the regions 302A, 302B, may vary. In some cases, the N-type and P-type SRAM devices 301N, 301P formed in the region 302A may each include a single fin, and the N-type and P-type SOC logic devices 303N, 303P formed in the region 302B may each include two fins. However, other embodiments are possible. For instance, in some examples, the N-type and P-type SRAM devices 301N, 301P formed in the region 302A may each alternatively include two fins. Further, in some embodiments, the N-type and P-type SOC logic devices 303N, 303P formed in the region 302B may each include a single fin.

In various embodiments, each of the N-type and P-type SRAM devices 301N, 301P, and the N-type and P-type SOC logic devices 303N, 303P also include gate stacks 316 formed over respective fins 302N, 302P, 304N, 304P within each of the regions 302A, 302B. In an embodiment, the gate stacks 316 are dummy (sacrificial) gate stacks that are subsequently removed and replaced by a final gate stack at a subsequent processing stage. For example, the gate stacks 316 may be replaced at a later processing stage by a high-K dielectric layer (HK) and metal gate electrode (MG). While the present discussion is directed to a replacement gate (gate-last) process whereby a dummy gate structure is formed and subsequently replaced, other configurations may be possible (e.g., such as a gate-first process). The portion of the fins 302N, 302P, 304N, 304P underlying their respective gate stacks 316 may be referred to as a channel region of the device. The gate stacks 316 may also define source/drain regions 318 of the fins 302N, 302P, 304N, 304P, for example, which includes the regions of the fins 302N, 302P, 304N, 304P adjacent to the gate stacks 316 and on opposing sides of the channel region.

In some embodiments, the gate stacks 316 include a dielectric layer and an electrode layer formed over the dielectric layer. In some embodiments, the dielectric layer of the gate stacks 316 includes silicon oxide. Alternatively, or additionally, the dielectric layer of the gate stacks 316 may include silicon nitride, a high-K dielectric material or other suitable material. In some embodiments, the electrode layer of the gate stacks 316 may include polycrystalline silicon (polysilicon). In some embodiments, one or more spacer layers 320 may be formed on sidewalls of the gate stacks 316. In some cases, the one or more spacer layers 320 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In some embodiments, the one or more spacer layers 320 include multiple layers, such as main spacer layers, liner layers, and the like.

In various examples, and because each of the SRAM devices and SOC logic devices have substantially the same CPP, the gate stacks 316 in the different regions 302A, 302B may also have substantially the same gate spacings S1. However, in at least some cases, the gate spacings in each of the different regions 302A, 302B may be different. Also, in various embodiments, a width of the gate stacks 316 in the regions 302A, 302B may be substantially the same, or they may be different.

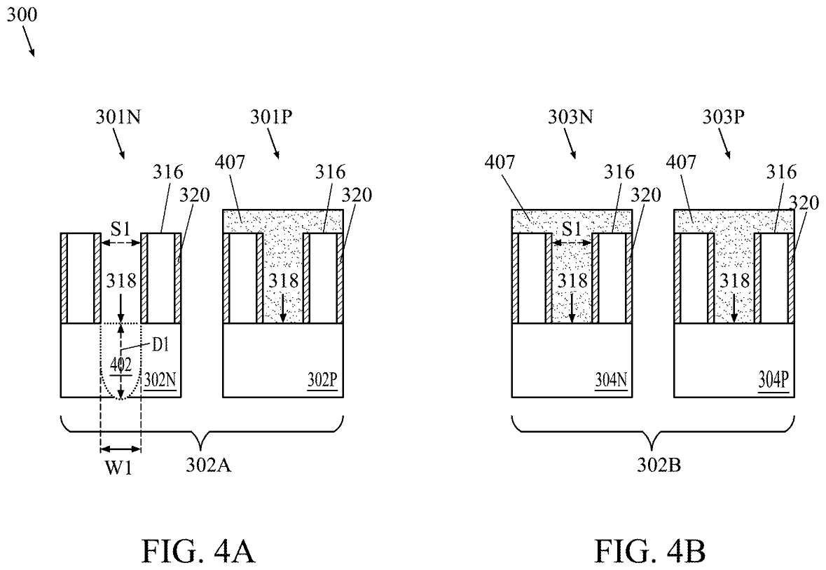

The method 200 proceeds to block 204 where a first photo/etch process for N-type S/D regions is performed. Referring to the example of FIGS. 4A, 4B, in an embodiment of block 204, a first photo/etch process is performed to form a source/drain recess 402 within the source/drain region 318 of the N-type SRAM device 301N. Initially, a mask layer may be deposited and patterned to form a patterned mask layer 407 having an opening which exposes the N-type SRAM device 301N while the P-type SRAM device 301P, and the N-type and P-type SOC logic devices 303N, 303P remain protected by the patterned mask layer 407. In some embodiments, the mask layer includes a photoresist (resist) layer and/or a hard mask layer (e.g., silicon oxide, silicon nitride, silicon oxynitride, silicon carbide, or other appropriate hard mask layer) such that the patterned mask layer 407 may include a patterned resist layer and/or a patterned hard mask layer. If only a resist layer is used, the deposited resist layer may be patterned (e.g., by exposure and development of the resist layer) to form the patterned mask layer 407. Alternatively, if a hard mask layer is used, a pattern may be initially formed in the resist layer (e.g., by exposure and development), after which the pattern may be transferred to an underlying hard mask layer (e.g., by etching) to form the patterned mask layer 407. In some embodiments, any remaining portion of the resist layer may be removed after patterning of the hard mask layer (e.g., such as by using an appropriate etchant, solvent, or ashing process).

In some embodiments, and due to the smaller dimensions of the opening formed in the patterned mask layer 407 to expose the N-type SRAM device 301N, the photomask used in the lithography process may be a high-grade photomask with high resolution, compared to a low-grade photomask that may be used during other photolithography processes and/or in other embodiments, as described below. Accordingly, the lithography system used in the lithography process used to form the patterned mask layer 407 may also be a high-grade lithography system with high resolution. For example, a high-grade photomask and lithography system may be associated with an extreme ultra-violet (EUV) light and an EUV lithography system having a resolution about several nanometers, while a low-grade photomask and lithography system may be associated with a deep ultra-violet (DUV) lithography system having a resolution about tens of nanometers. In another example, a high-grade photomask and lithography system may be associated with a DUV lithography system using argon fluoride (ArF) excimer laser and having a resolution of about 65 nm, while a low-grade photomask and lithography system may be associated with a DUV lithography system using krypton fluoride (KrF) excimer laser and having a resolution of about 130 nm.

Whether or not a hard mask layer is used, and after exposure of the N-type SRAM device 301N, an etching process (e.g., wet etch, dry etch, or combination thereof) is performed to remove portions of the fin 302N in the source/drain region 318 of the N-type SRAM device 301N to form the source/drain recess 402. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recess 402, the patterned mask layer 407 is removed (e.g., such as by using an appropriate etchant, solvent, or ashing process).

As shown in FIG. 4A, the source/drain recess 402 is etched to a depth D1 and a width W1. It is noted that the etching process to form the source/drain recess 402 (having the width W1) may effectively define a S/D proximity (e.g., a distance between a source and a drain) for the N-type SRAM device 301N. Thus, the distance (or spacing) between a source and drain of the N-type SRAM device 301N is directly related to the width W1 of the source/drain recess 402. For example, a larger width W1 would result in a smaller S/D proximity, and a smaller width W1 would result in a larger S/D proximity. It is also noted that the depth D1 of the source/drain recess 402 may be designed to be shallower, as compared to SOC logic devices, to provide tighter control of SCEs.

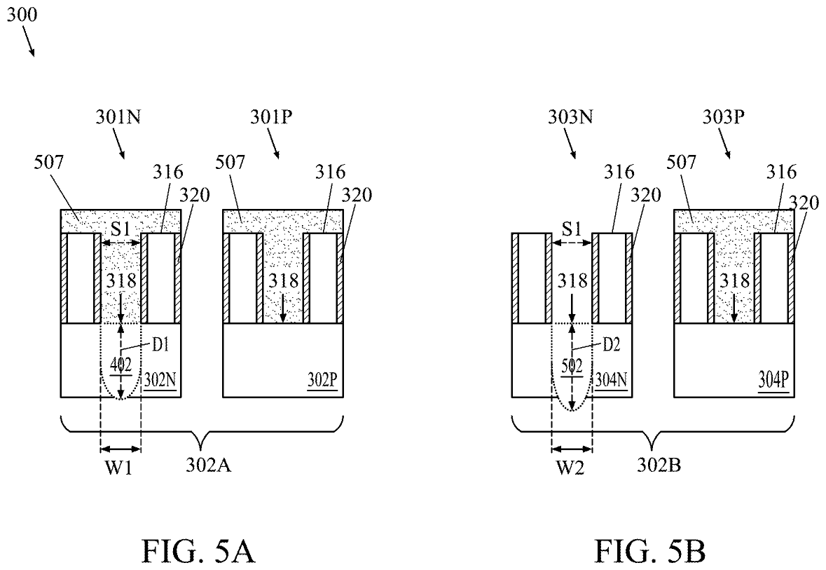

The method 200 proceeds to block 206 where a second photo/etch process for N-type S/D regions is performed. Referring to the example of FIGS. 5A, 5B, in an embodiment of block 206, a second photo/etch process is performed to form a source/drain recess 502 within the source/drain region 318 of the N-type SOC logic device 303N. Initially, a mask layer may be deposited and patterned to form a patterned mask layer 507 having an opening which exposes the N-type SOC logic device 303N while the N-type and P-type SRAM devices 301N, 301P, and the P-type SOC logic device 303P remain protected by the patterned mask layer 507. In some embodiments, the mask layer includes a resist layer and/or a hard mask layer (e.g., silicon oxide, silicon nitride, silicon oxynitride, silicon carbide, or other appropriate hard mask layer) such that the patterned mask layer 507 may include a patterned resist layer and/or a patterned hard mask layer. If only a resist layer is used, the deposited resist layer may be patterned (e.g., by exposure and development of the resist layer) to form the patterned mask layer 507. Alternatively, if a hard mask layer is used, a pattern may be initially formed in the resist layer (e.g., by exposure and development), after which the pattern may be transferred to an underlying hard mask layer (e.g., by etching) to form the patterned mask layer 507. In some cases, any remaining portion of the resist layer may be removed after patterning of the hard mask layer (e.g., such as by using an appropriate etchant, solvent, or ashing process). In some embodiments, and once again due to the smaller dimensions of the opening formed in the patterned mask layer 507 to expose the N-type SOC logic device 303N, formation of the patterned mask layer 507 may include use of a high-grade photomask and a lithography system with high resolution, as discussed above.

Whether or not a hard mask layer is used, and after exposure of the N-type SOC logic device 303N, an etching process (e.g., wet etch, dry etch, or combination thereof) is performed to remove portions of the fin 304N in the source/drain region 318 of the N-type SOC logic device 303N to form the source/drain recess 502. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recess 502, the patterned mask layer 507 is removed (e.g., such as by using an appropriate etchant, solvent, or ashing process).

As shown in FIG. 5B, the source/drain recess 502 is etched to a depth D2 and a width W2. In some embodiments, because the source/drain recess 502 of the N-type SOC logic device 303N is formed separately from that of the N-type SRAM device 301N, the S/D depth of each of the N-type SRAM device 301N and the N-type SOC logic device 303N can be independently controlled and optimized. In some embodiments, the depth D2 of the source/drain recess 502 of the N-type SOC logic device 303N is greater than (deeper than) the depth D1 of the source/drain recess 402 of the N-type SRAM device 301N, thereby providing higher current/performance for the N-type SOC logic device 303N. The etching process to form the source/drain recess 502 (having the width W2) also effectively defines the S/D proximity for the N-type SOC logic device 303N. In at least some examples, the width W1 of the recess 402 and the width W2 of the recess 502 are substantially the same. Thus, in some cases, the N-type SOC logic device 303N will have substantially the same distance between a source and drain as the N-type SRAM device 301N. However, in some embodiments, the width W1 of the recess 402 and the width W2 of the recess 502 may be different, resulting in a different proximity (spacing between source and drain) for each of the N-type SOC logic device 303N and the N-type SRAM device 301N.

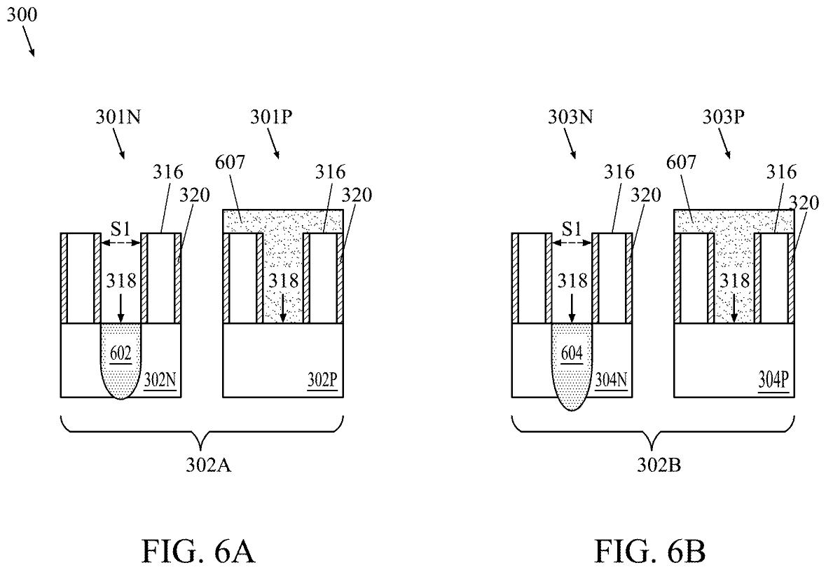

The method 200 then proceeds to block 208 where N-type source/drain features are formed. Referring to FIGS. 6A, 6B, in an embodiment of block 208, N-type source/drain features 602 are formed in the source/drain recess 402 of the N-type SRAM device 301N, and N-type source/drain features 604 are formed in the source/drain recess 502 of the N-type SOC logic device 303N. In some embodiments, the source/drain features 602, 604 are formed in the source/drain regions 318 adjacent to and on either side of the gate stacks 316 of each of the N-type SRAM device 301N and the N-type SOC logic device 303N. In some embodiments, a clean process may be performed immediately prior to formation of the source/drain features 602, 604. The clean process may include a wet etch, a dry etch, or a combination thereof.

In some examples, prior to forming the N-type source/drain features 602, 604, a mask layer may be deposited and patterned to form a patterned mask layer 607 having openings which expose the N-type SRAM device 301N and the N-type SOC logic device 303N, while the P-type SRAM device 301P and the P-type SOC logic device 303P remain protected by the patterned mask layer 607. In some embodiments, the mask layer includes a resist layer and/or a hard mask layer (e.g., silicon oxide, silicon nitride, silicon oxynitride, silicon carbide, or other appropriate hard mask layer) such that the patterned mask layer 607 may include a patterned resist layer and/or a patterned hard mask layer. If only a resist layer is used, the deposited resist layer may be patterned (e.g., by exposure and development of the resist layer) to form the patterned mask layer 607. Alternatively, if a hard mask layer is used, a pattern may be initially formed in the resist layer (e.g., by exposure and development), after which the pattern may be transferred to an underlying hard mask layer (e.g., by etching) to form the patterned mask layer 607. In some cases, any remaining portion of the resist layer may be removed after patterning of the hard mask layer (e.g., such as by using an appropriate etchant, solvent, or ashing process). In some embodiments, the openings in the patterned mask layer 607 which expose the N-type SRAM device 301N and the N-type SOC logic device 303N may be formed using a high-grade photomask and a lithography system with high resolution, as discussed above. Whether or not a hard mask layer is used, and after exposure of the N-type SRAM device 301N and the N-type SOC logic device 303N, the N-type source/drain features 602, 604 may be formed. After formation of the N-type source/drain features 602, 604, the patterned mask layer 607 is removed (e.g., such as by using an appropriate etchant, solvent, or ashing process).

In some embodiments, the source/drain features 602, 604 are formed by epitaxially growing a semiconductor material layer in the source/drain regions 318. By way of example, the semiconductor material layer grown to form the source/drain features 602, 604 may include Ge, Si, GaAs, AlGaAs, SiGe, GaAsP, SiP, or other suitable material. The source/drain features 602, 604 may be formed by one or more epitaxial (epi) processes. In some embodiments, the source/drain features 602, 604 may be in-situ doped during the epi process. For example, in some embodiments, the source/drain features 602, 604 are doped with an N-type dopant species such as phosphorous, arsenic, antimony, or other suitable dopant species such as carbon. In some examples, the source/drain features 602, 604 may include SiC or Si doped with phosphorous. In some embodiments, the source/drain features 602, 604 are not in-situ doped, and instead an implantation process is performed to dope the source/drain features 602, 604. In various examples, and after formation of the source/drain features 602, 604, an annealing process may be performed (e.g., such as a rapid thermal anneal, laser anneal, or other suitable annealing process). It is noted that in some embodiments, the source/drain features 602, 604 may be epitaxially grown such that they extend above a top surface of their respective fins 302N, 304N, being referred to as raised source/drain features. In accordance with the embodiments disclosed herein, the N-type source/drain features 602, 604 are thus effectively co-optimized for the N-type SRAM device 301N and the N-type SOC logic device 303N.

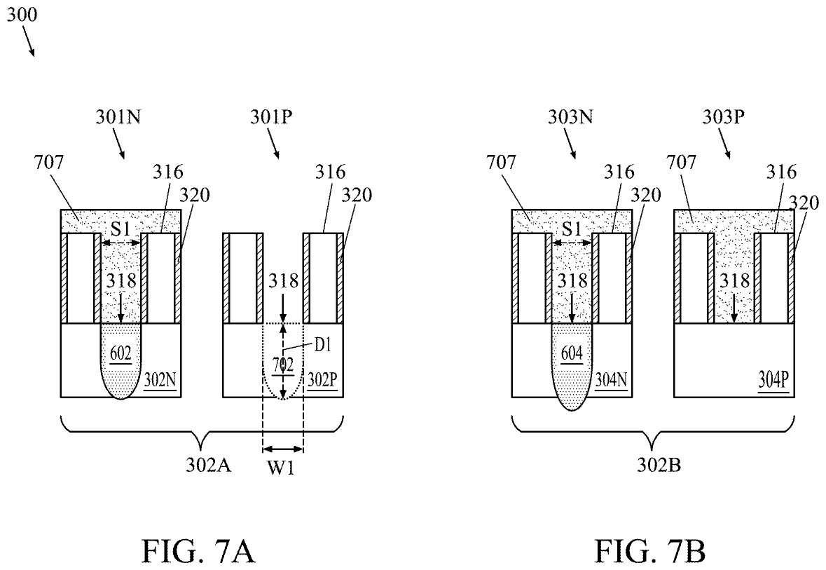

The method 200 proceeds to block 210 where a first photo/etch process for P-type S/D regions is performed. Referring to the example of FIGS. 7A, 7B, in an embodiment of block 210, a first photo/etch process is performed to form a source/drain recess 702 within the source/drain region 318 of the P-type SRAM device 301P. Initially, a mask layer may be deposited and patterned to form a patterned mask layer 707 having an opening which exposes the P-type SRAM device 301P while the N-type SRAM device 301N, and the N-type and P-type SOC logic devices 303N, 303P remain protected by the patterned mask layer 707. In some embodiments, the mask layer includes a resist layer and/or a hard mask layer (e.g., silicon oxide, silicon nitride, silicon oxynitride, silicon carbide, or other appropriate hard mask layer) such that the patterned mask layer 707 may include a patterned resist layer and/or a patterned hard mask layer. If only a resist layer is used, the deposited resist layer may be patterned (e.g., by exposure and development of the resist layer) to form the patterned mask layer 707. Alternatively, if a hard mask layer is used, a pattern may be initially formed in the resist layer (e.g., by exposure and development), after which the pattern may be transferred to an underlying hard mask layer (e.g., by etching) to form the patterned mask layer 707. In some cases, any remaining portion of the resist layer may be removed after patterning of the hard mask layer (e.g., such as by using an appropriate etchant, solvent, or ashing process). In some embodiments, the opening in the patterned mask layer 707 which exposes the P-type SRAM device 301P may be formed using a high-grade photomask and a lithography system with high resolution, for example, due to the smaller dimensions of the opening formed in the patterned mask layer 707. Whether or not a hard mask layer is used, and after exposure of the P-type SRAM device 301P, an etching process (e.g., wet etch, dry etch, or combination thereof) is performed to remove portions of the fin 302P in the source/drain region 318 of the P-type SRAM device 301P to form the source/drain recess 702. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recess 702, the patterned mask layer 707 is removed (e.g., such as by using an appropriate etchant, solvent, or ashing process).

As shown in FIG. 7A, the source/drain recess 702 is etched to the depth D1 and the width W1, similar to the depth and width of the source/drain recess 402 formed in the N-type SRAM device 301N. It is noted that the etching process to form the source/drain recess 702 (having the width W1) may effectively define the S/D proximity for the P-type SRAM device 301P. Thus, the distance (or spacing) between a source and drain of the P-type SRAM device 301P is directly related to the width W1 of the source/drain recess 702. As in the case of the N-type SRAM device 301N, the depth D1 of the source/drain recess 702 for the P-type SRAM device 301P may be designed to be shallower, as compared to SOC logic devices, to provide tighter control of SCEs.

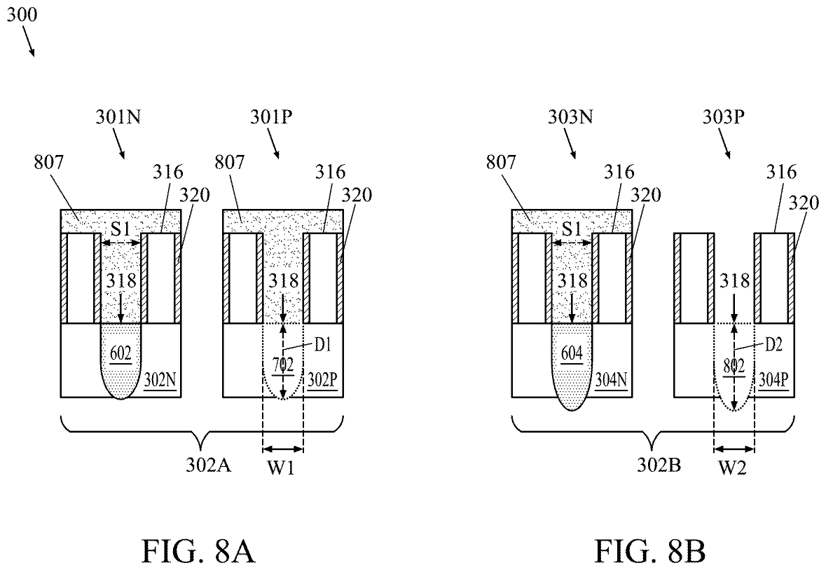

The method 200 proceeds to block 212 where a second photo/etch process for P-type S/D regions is performed. Referring to the example of FIGS. 8A, 8B, in an embodiment of block 212, a second photo/etch process is performed to form a source/drain recess 802 within the source/drain region 318 of the P-type SOC logic device 303P. Initially, a mask layer may be deposited and patterned to form a patterned mask layer 807 having an opening which exposes the P-type SOC logic device 303P while the N-type and P-type SRAM devices 301N, 301P, and the N-type SOC logic device 303N remain protected by the patterned mask layer 807. In some embodiments, the mask layer includes a resist layer and/or a hard mask layer (e.g., silicon oxide, silicon nitride, silicon oxynitride, silicon carbide, or other appropriate hard mask layer) such that the patterned mask layer 807 may include a patterned resist layer and/or a patterned hard mask layer. If only a resist layer is used, the deposited resist layer may be patterned (e.g., by exposure and development of the resist layer) to form the patterned mask layer 807. Alternatively, if a hard mask layer is used, a pattern may be initially formed in the resist layer (e.g., by exposure and development), after which the pattern may be transferred to an underlying hard mask layer (e.g., by etching) to form the patterned mask layer 807. In some cases, any remaining portion of the resist layer may be removed after patterning of the hard mask layer (e.g., such as by using an appropriate etchant, solvent, or ashing process). In some embodiments, the opening in the patterned mask layer 807 which exposes the P-type SOC logic device 303P may be formed using a high-grade photomask and a lithography system with high resolution, for example, due to the smaller dimensions of the opening formed in the patterned mask layer 807. Whether or not a hard mask layer is used, and after exposure of the P-type SOC logic device 303P, an etching process (e.g., wet etch, dry etch, or combination thereof) is performed to remove portions of the fin 304P in the source/drain region 318 of the P-type SOC logic device 303P to form the source/drain recess 802. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recess 802, the patterned mask layer 807 is removed (e.g., such as by using an appropriate etchant, solvent, or ashing process).

As shown in FIG. 8B, the source/drain recess 802 is etched to the depth D2 and the width W2, similar to the depth and width of the source/drain recess 502 formed in the N-type SOC logic device 303N. In some embodiments, because the source/drain recess 802 of the P-type SOC logic device 303P is formed separately from that of the P-type SRAM device 301P, the S/D depth of each of the P-type SRAM device 301P and the P-type SOC logic device 303P can be independently controlled and optimized. In some embodiments, the depth D2 of the source/drain recess 802 of the P-type SOC logic device 303P is greater than (deeper than) the depth D1 of the source/drain recess 702 of the P-type SRAM device 301P, thereby providing higher current/performance for the P-type SOC logic device 303P. The etching process to form the source/drain recess 802 (having the width W2) also effectively defines the S/D proximity for the P-type SOC logic device 303P. In at least some examples, the width W1 of the recess 702 and the width W2 of the recess 802 are substantially the same. Thus, in some cases, the P-type SOC logic device 303P will have substantially the same distance between a source and drain as the P-type SRAM device 301P. However, in some embodiments, the width W1 of the recess 702 and the width W2 of the recess 802 may be different, resulting in a different proximity (spacing between source and drain) for each of the P-type SOC logic device 303P and the P-type SRAM device 301P.

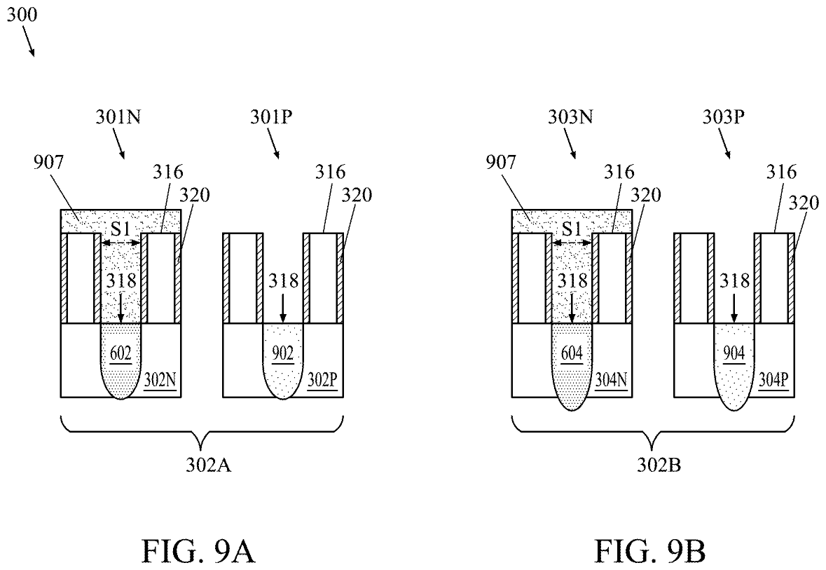

The method 200 then proceeds to block 214 where P-type source/drain features are formed. Referring to FIGS. 9A, 9B, in an embodiment of block 214, P-type source/drain features 902 are formed in the source/drain recess 702 of the P-type SRAM device 301P, and P-type source/drain features 904 are formed in the source/drain recess 802 of the P-type SOC logic device 303P. In some embodiments, the source/drain features 902, 904 are formed in the source/drain regions 318 adjacent to and on either side of the gate stacks 316 of each of the P-type SRAM device 301P and the P-type SOC logic device 303P. In some embodiments, a clean process may be performed immediately prior to formation of the source/drain features 902, 904. The clean process may include a wet etch, a dry etch, or a combination thereof.

In some examples, prior to forming the P-type source/drain features 902, 904, a mask layer may be deposited and patterned to form a patterned mask layer 907 having openings which expose the P-type SRAM device 301P and the P-type SOC logic device 303P, while the N-type SRAM device 301N and the N-type SOC logic device 303N remain protected by the patterned mask layer 907. In some embodiments, the mask layer includes a resist layer and/or a hard mask layer (e.g., silicon oxide, silicon nitride, silicon oxynitride, silicon carbide, or other appropriate hard mask layer) such that the patterned mask layer 907 may include a patterned resist layer and/or a patterned hard mask layer. If only a resist layer is used, the deposited resist layer may be patterned (e.g., by exposure and development of the resist layer) to form the patterned mask layer 907. Alternatively, if a hard mask layer is used, a pattern may be initially formed in the resist layer (e.g., by exposure and development), after which the pattern may be transferred to an underlying hard mask layer (e.g., by etching) to form the patterned mask layer 907. In some cases, any remaining portion of the resist layer may be removed after patterning of the hard mask layer (e.g., such as by using an appropriate etchant, solvent, or ashing process). In some embodiments, the openings in the patterned mask layer 907 which expose the P-type SRAM device 301P and the P-type SOC logic device 303P may be formed using a high-grade photomask and a lithography system with high resolution, as discussed above. Whether or not a hard mask layer is used, and after exposure of the P-type SRAM device 301P and the P-type SOC logic device 303P, the P-type source/drain features 902, 904 may be formed. After formation of the P-type source/drain features 902, 904, the patterned mask layer 907 is removed (e.g., such as by using an appropriate etchant, solvent, or ashing process).

In some embodiments, the source/drain features 902, 904 are formed by epitaxially growing a semiconductor material layer in the source/drain regions 318. In various embodiments, the semiconductor material layer grown to form the source/drain features 902, 904 may include Ge, Si, GaAs, AlGaAs, SiGe, GaAsP, SiP, or other suitable material. The source/drain features 902, 904 may be formed by one or more epitaxial (epi) processes. In some embodiments, the source/drain features 902, 904 may be in-situ doped during the epi process. For example, in some embodiments, the source/drain features 902, 904 are doped with a P-type dopant species such as boron, BF₂, or other suitable dopant species such as carbon. In some examples, the source/drain features 902, 904 may include SiGe or Si doped with boron. In some embodiments, the source/drain features 902, 904 are not in-situ doped, and instead an implantation process is performed to dope the source/drain features 902, 904. In various examples, and after formation of the source/drain features 902, 904, an annealing process may be performed (e.g., such as a rapid thermal anneal, laser anneal, or other suitable annealing process). It is noted that in some embodiments, the source/drain features 902, 904 may be epitaxially grown such that they extend above a top surface of their respective fins 302P, 304P, being referred to as raised source/drain features. In accordance with the embodiments disclosed herein, the P-type source/drain features 902, 904 are thus effectively co-optimized for the P-type SRAM device 301P and the P-type SOC logic device 303P.

For purposes of illustration and with reference to FIGS. 10A, 10B, illustrated therein are cross-sectional views of embodiments of the device 300 including the N-type and P-type SRAM devices 301N, 301P formed in the region 302A, and the N-type and P-type SOC logic devices 303N, 303P formed in the region 302B, along a plane substantially parallel to a plane defined by section BB′ of FIG. 1 after formation of the P-type source/drain features 902, 904. In the exemplary embodiment shown, the N-type and P-type SRAM devices 301N, 301P formed in the region 302A each include a single fin 302N, 302P, and the N-type and P-type SOC logic devices 303N, 303P formed in the region 302B each include two fins 304N, 304P. In addition, the N-type source/drain features 602, 604 are formed over their respective fins 302N, 304N, and the P-type source/drain features 902, 904 are formed over their respective fins 302P, 304P, as discussed above. Since the source/drain depth for the SOC logic devices 303N, 303P (D2) is greater than (deeper than) the source/drain depth for the SRAM devices 301N, 301P (D1), the bottommost portions of the source/drain features for each of the SRAM devices and the SOC logic devices will be offset by an amount equal to the difference between the depth D2 and the depth D1 (D2−D1), as shown. It is further noted that in some cases, such as in the illustrated example where the N-type and P-type SOC logic devices 303N, 303P each include two fins 304N, 304P, the source/drain features formed on adjacent fins may merge together during epitaxial growth. For example, the N-type source/drain features 604 formed on adjacent fins 304N may merge together, and the P-type source/drain features 904 formed on adjacent fins 304P may merge together. In some alternative embodiments, such as when the N-type and P-type SRAM devices 301N, 301P each include two fins, the source/drain features formed on adjacent fins may likewise merge together. The examples of FIGS. 10A, 10B also illustrate STI features 1002 that may be formed to isolate each of the fins 302N, 302P, 304N, 304P from neighboring fins, as well as sidewall spacer layers 1004 that may be formed on sidewalls of the fins prior to formation of the source/drain features.

The method 200 then proceeds to block 216 where further processing is performed. For example, after formation of the P-type source/drain features and removal of the patterned mask layer 907 (block 214), a contact etch stop layer (CESL) and an inter-layer dielectric (ILD) layer are formed over the device 300 and a chemical mechanical polishing (CMP) process is performed. In some embodiments, the CMP process may expose a top surface of the gate stacks 316 (e.g., by removing portions of the ILD layer and CESL) overlying the gate stacks 316 and planarize a top surface of the device 300. In addition, the CMP process may remove any hard mask layers overlying the gate stacks 316, if any, to expose the underlying electrode layer of the gate stacks 316, such as a polysilicon electrode layer. In a further embodiment of block 216, the exposed electrode layer of the gate stacks 316 may initially be removed by suitable etching processes, followed by an etching process to remove the dielectric layer of the gate stacks 316 within each of the regions 302A, 302B. In some examples, the etching processes may include a wet etch, a dry etch, or a combination thereof.

After removal of the dummy gates (e.g., the gate stacks 316), and in a further embodiment of block 216, a gate structure is formed over the N-type and P-type devices within each of the regions 302A, 302B. The gate structure may include a high-K/metal gate stack, however other compositions are possible. In some embodiments, the gate structure may form the gate associated with each of the N-type and P-type SRAM devices 301N, 301P and the N-type and P-type SOC logic devices 303N, 303P. In some embodiments, the gate structure includes an interfacial layer (IL) (e.g., such as silicon oxide (SiO₂), HfSiO, or silicon oxynitride) and a high-K dielectric layer formed over the IL. In some embodiments, the high-K dielectric layer may include hafnium oxide (HfO₂). Alternatively, the high-K dielectric layer may include TiO₂, HfZrO, Ta₂O₃, HfSiO₄, ZrO₂, ZrSiO₂, LaO, Al0, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. In various embodiments, the IL and the high-K dielectric layer collectively define a gate dielectric of the gate structure.

In a further embodiment of block 216, a metal gate including a metal layer is formed over the gate dielectric (e.g., over the IL and the high-K dielectric layer). The metal layer may include a metal, metal alloy, or metal silicide. In various examples, the metal layer may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. Additionally, the formation of the gate dielectric/metal gate stack may include depositions to form various gate materials, one or more liner layers, and one or more CMP processes to remove excessive gate materials and thereby planarize a top surface of the device 300.

Generally, the semiconductor device 300 may undergo further processing to form various features and regions known in the art. For example, further processing may form various contacts/vias/lines and multilayer interconnect features (e.g., metal layers and interlayer dielectrics) on the substrate, configured to connect the various features to form a functional circuit that may include one or more multi-gate devices (e.g., FinFET devices). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be modified, replaced, or eliminated in accordance with various embodiments of the method 200.

For example, while the method 200 has been described as first forming the N-type source/drain regions and then the P-type source/drain regions, it will be understood that is some cases the P-type source/drain regions may be formed before the N-type source/drain regions. Further, while the method 200 was described as performed using a two-step photo/etch process (2P2E) for each of an N-type S/D and a P-type S/D for the various device types (e.g., the SRAM and SOC logic devices), other embodiments are possible. For instance, instead of performing first and second photo/etch processes for N-type source/drain regions (blocks 204, 206 of the method 200) and first and second photo/etch processes for P-type source/drain regions (blocks 210, 212 of the method 200), some embodiments may include performing first and second photo/etch processes for only one of the N-type source/drain regions or the P-type source/drain regions, and performing a single photo/etch process for the other of the N-type source/drain regions or the P-type source/drain regions. As a result, in some cases, only one of the N-type source/drain regions or the P-type source/drain regions for the various device types (e.g., the SRAM and SOC logic devices) may have different depths.

For instance, a single photo/etch process (1P1E) can be used to simultaneously form source/drain recesses in source/drain regions of each of the various N-type devices (e.g., the N-type SRAM and SOC logic devices) within which N-type source/drain features are subsequently formed, while a two-step photo/etch process (2P2E) is used for the P-type S/D for the various device types (e.g., the P-type SRAM and SOC logic devices) as described above with reference to blocks 210, 212 of the method 200. In this example, only the P-type source/drain regions of the various device types (e.g., the SRAM and SOC logic devices) may have different depths, while the N-type source/drain regions have substantially the same depth. Alternatively, a single photo/etch process (1P1E) can be used to simultaneously form source/drain recesses in source/drain regions of each of the various P-type devices (e.g., the P-type SRAM and SOC logic devices) within which P-type source/drain features are subsequently formed, while a two-step photo/etch process (2P2E) is used for the N-type S/D for the various device types (e.g., the N-type SRAM and SOC logic devices) as described above with reference to blocks 204, 206 of the method 200. In this example, only the N-type source/drain regions of the various device types (e.g., the SRAM and SOC logic devices) may have different depths, while the P-type source/drain regions have substantially the same depth. While various exemplary modifications to the method 200 have been discussed, it will be understood that the above examples are merely illustrative and not meant to be limiting. Those of skill in the art, having the benefit of the present disclosure, will understand that yet other embodiments and/or modifications are possible, without departing from the scope of this disclosure.

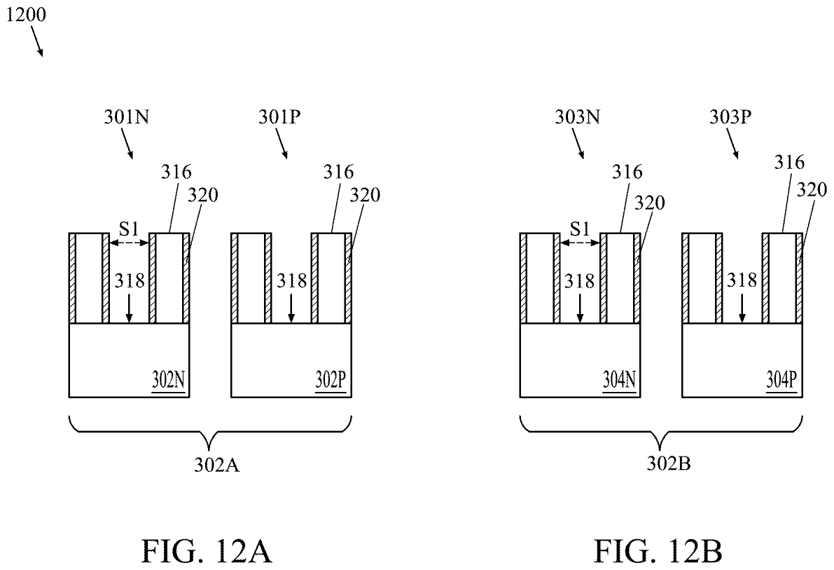

Referring now to FIG. 11, illustrated therein is a method 1100 of semiconductor fabrication including fabrication of a semiconductor device 1200 having various device types (e.g., such as an SOC logic devices and SRAM devices) formed on a given substrate and that are co-optimized, for example by controlling S/D depth, in accordance with various embodiments. Embodiments of the method 1100 are described below with reference to FIGS. 12A/12B-17A/17B, which provide cross-sectional views of embodiments of the device 1200 along a plane substantially parallel to a plane defined by section AA′ of FIG. 1. In some embodiments, the co-optimization described with respect to the method 1100 may be performed using an implantation-enhanced S/D recess process, using at least one low-grade photomask and lithography system, to provide the different source/drain depths for the various device types. The implantation-enhanced S/D recess process may be accomplished at a reduced cost using simplified lithography, for example, as compared to the 2-step or multi-step S/D recess described above with reference to the method 200. The method 1100 has some similarities to the method 200 of FIG. 11. Thus, while every feature of the method 200 may not be repeated below in the discussion of the method 1100, it will be understood that one or more aspects discussed above with reference to the method 200 equally apply to the method 1100. In addition, for the sake of clarity of discussion and throughout the present disclosure, like reference numerals may be used to denote like features unless otherwise described. Therefore, like reference numerals may be used to denote various features in FIGS. 12A/12B-17A/17B, where such features are similar or substantially the same as corresponding features discussed above with reference to the method 200.

The method 1100 begins at block 1102 where a substrate including a partially fabricated device is provided. Referring to the example of FIGS. 12A, 12B, in an embodiment of block 1102, partially fabricated N-type and P-type SRAM devices 301N, 301P are provided in a region 302A of a substrate, and partially fabricated N-type and P-type SOC logic devices 303N, 303P are provided in a region 302B of the substrate.

As in the device 300 discussed above, each of the N-type and P-type SRAM devices 301N, 301P, and the N-type and P-type SOC logic devices 303N, 303P of the device 1200 may be formed within different regions 302A, 302B of the same substrate, such as a silicon substrate or other appropriate substrate, as previously described. The N-type and P-type SRAM devices 301N, 301P include fins 302N, 302P and the N-type and P-type SOC logic devices 303N, 303P include fins 304N, 304P. In various embodiments, the fins 302N, 302P, 304N, 304P may be formed of the same material or a different material as the underlying substrate from which they extend. In addition, STI features may also be formed to isolate each of the fins 302N, 302P, 304N, 304P from neighboring fins. Also, as described above, the number of fins used to form each of the N-type and P-type SRAM devices 301N, 301P, and the N-type and P-type SOC logic devices 303N, 303P, within each of the regions 302A, 302B, may vary.

Each of the N-type and P-type SRAM devices 301N, 301P, and the N-type and P-type SOC logic devices 303N, 303P also include gate stacks 316 formed over respective fins 302N, 302P, 304N, 304P within each of the regions 302A, 302B. The gate stacks 316 may be dummy (sacrificial) gate stacks that are subsequently removed and replaced by a final gate stack at a subsequent processing stage. The gate stacks 316 also define source/drain regions 318 of the fins 302N, 302P, 304N, 304P, for example, which includes the regions of the fins 302N, 302P, 304N, 304P adjacent to the gate stacks 316 and on opposing sides of the channel region. In various embodiments, the gate stacks 316 include a dielectric layer and an electrode layer formed over the dielectric layer, as previously discussed, and one or more spacer layers 320 may be formed on sidewalls of the gate stacks 316. In some cases, after the block 1102, a portion of the one or more spacer layers 320 may remain disposed between the gate stacks 316, over the source/drain regions 318, during a subsequent ion implantation process (block 1104). Alternatively, in some embodiments, a dielectric layer may be separately formed between the gate stacks 316, over the source/drain regions 318, prior to the subsequent ion implantation process.

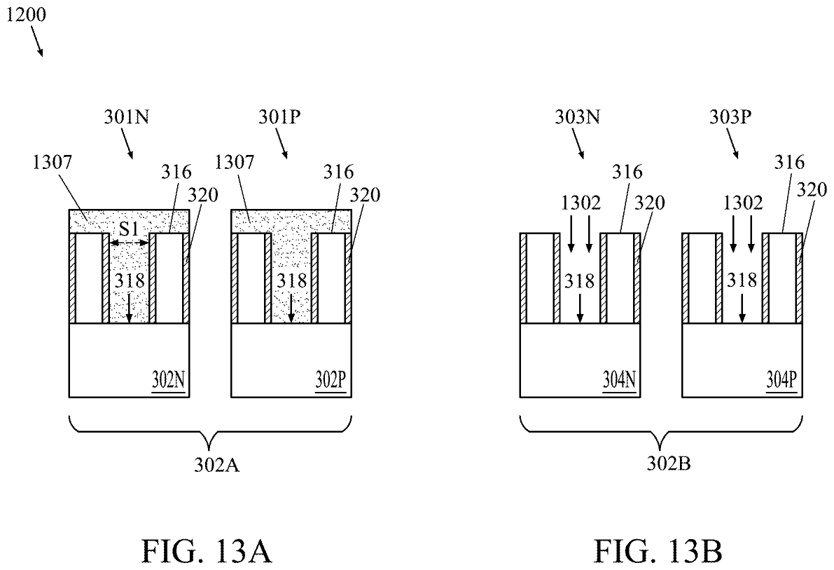

The method 1100 proceeds to block 1104 where an ion implantation process is performed into a logic device region. Referring to the example of FIGS. 13A, 13B, in an embodiment of block 1104, an ion implantation process 1302 is performed into the source/drain regions 318 of the N-type SOC logic device 303N and the P-type SOC logic device 303P. Initially, a mask layer may be deposited and patterned to form a patterned mask layer 1307 having an opening which exposes the N-type SOC logic device 303N and the P-type SOC logic device 303P, while the N-type SRAM device 301N and the P-type SRAM device 301P remain protected by the patterned mask layer 1307. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1307 may include a patterned resist layer and/or a patterned hard mask layer. If only a resist layer is used, the deposited resist layer may be patterned (e.g., by exposure and development of the resist layer) to form the patterned mask layer 1307. Alternatively, if a hard mask layer is used, a pattern may be initially formed in the resist layer (e.g., by exposure and development), after which the pattern may be transferred to an underlying hard mask layer (e.g., by etching) to form the patterned mask layer 1307. In some embodiments, any remaining portion of the resist layer may be removed after patterning of the hard mask layer (e.g., such as by using an appropriate etchant, solvent, or ashing process). In some examples, and due to the larger dimensions of the opening formed in the patterned mask layer 1307 to expose both the N-type SOC logic device 303N and the P-type SOC logic device 303P, formation of the patterned mask layer 1307 may include use of a low-grade photomask and a lithography system with low resolution, as compared to the high-grade photomask and lithography system with high resolution, discussed above.

Whether or not a hard mask layer is used, and after exposure of the N-type SOC logic device 303N and the P-type SOC logic device 303P, an ion implantation process is performed to introduce a dopant species into the source/drain regions 318 of the N-type SOC logic device 303N and the P-type SOC logic device 303P. The dopant species is introduced into the source/drain regions 318 but not into the channels (portions of the fins underlying the gate stacks 316) since the channels remain covered by the gate stacks 316. In some embodiments, the dopant species includes at least one of carbon (C), silicon (Si), germanium (Ge), hydrogen (H), nitrogen (N), fluorine (F), argon (Ar), and a combination thereof. Alternatively, or additionally, the dopant species includes at least one of gallium (Ga), phosphorous (P), arsenic (As), and a combination thereof. In some cases, the implantation process is performed at an angle that is substantially perpendicular to the substrate (e.g., at a tilt angle of about zero degrees), although other implant angles are possible. In some embodiments, the ion implantation process is performed through the portion of the one or more spacer layers 320 or the separately formed dielectric layer, if present, between the gate stacks 316 and over the source/drain regions 318. The purpose of implanting the dopant species into the source/drain regions 318 is to modify the etch rate of the source/drain regions 318 during a subsequent etching process to recess the source/drain regions 318. In the present example, the etch rate of the implanted source/drain regions 318 of the N-type SOC logic device 303N and the P-type SOC logic device 303P is increased. In some cases, the increased etch rate is due to damage to the source/drain regions 318 caused by the implanted dopant ions, which cause structural changes (e.g., such as defect formation) and accordingly increase the etch rate of the implanted regions. In some embodiments, the doping concentration of the implanted dopant species ranges between 1×10¹⁹ and 1×10²² (cm³). The corresponding implantation dose ranges between 1×10¹⁴ and 1×10¹⁶ (cm²). In addition, the ion implantation process includes a bias power ranging between 1K eV and 4K eV to provide the intended damage and etch rate variation. After performing the ion implantation process, the patterned mask layer 1307 is removed (e.g., such as by using an appropriate etchant, solvent, or ashing process).

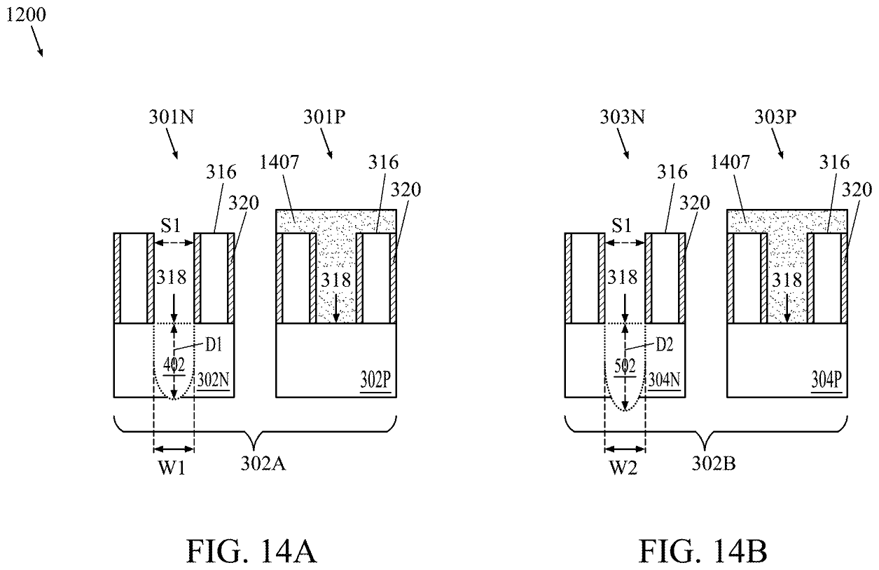

The method 1100 proceeds to block 1106 where a photo/etch process for N-type S/D regions is performed. Referring to the example of FIGS. 14A, 14B, in an embodiment of block 1106, a photo/etch process is performed to simultaneously form a source/drain recess 402 within the source/drain region 318 of the N-type SRAM device 301N and a source/drain recess 502 within the source/drain region 318 of the N-type SOC logic device 303N. Initially, a mask layer may be deposited and patterned to form a patterned mask layer 1407 having openings which expose the N-type SRAM device 301N and the N-type SOC logic device 303N while the P-type SRAM device 301P and the P-type SOC logic device 303P remain protected by the patterned mask layer 1407. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1407 may include a patterned resist layer and/or a patterned hard mask layer, as previously described. In some embodiments, and due to the smaller dimensions of the openings formed in the patterned mask layer 1407 to expose the N-type SRAM device 301N and the N-type SOC logic device 303N, formation of the patterned mask layer 1407 may include use of a high-grade photomask and a lithography system with high resolution, as discussed above.

Whether or not a hard mask layer is used, and after exposure of the N-type SRAM device 301N and the N-type SOC logic device 303N, an etching process (e.g., wet etch, dry etch, or combination thereof) is performed to remove portions of the fins 302N, 304N in the source/drain region 318 of the N-type SRAM device 301N and the N-type SOC logic device 303N to form the source/drain recesses 402, 502. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recess 402, 502, the patterned mask layer 1407 is removed (e.g., such as by using an appropriate etchant, solvent, or ashing process).

As shown in FIGS. 14A and 14B, the source/drain recess 402 is etched to the depth D1 and the width W1, and the source/drain recess 502 is etched to the depth D2 and the width W2. Due to the ion implantation process, and the associated increased etch rate of the source/drain region 318 of the N-type SOC logic device 303N, the depth D2 of the source/drain recess 502 of the N-type SOC logic device 303N is greater than (deeper than) the depth D1 of the source/drain recess 402 of the N-type SRAM device 301N, thereby simultaneously providing tighter control of SCEs for the N-type SRAM device 301N and higher current/performance for the N-type SOC logic device 303N. Even though the recesses 402, 502 may be formed simultaneously, the varied etch rate of the source/drain regions 318 provided by the ion implantation process nevertheless ensures that the S/D depth of each of the N-type SRAM device 301N and the N-type SOC logic device 303N can be independently controlled and optimized (e.g., by controlling process parameters of the ion implantation process).

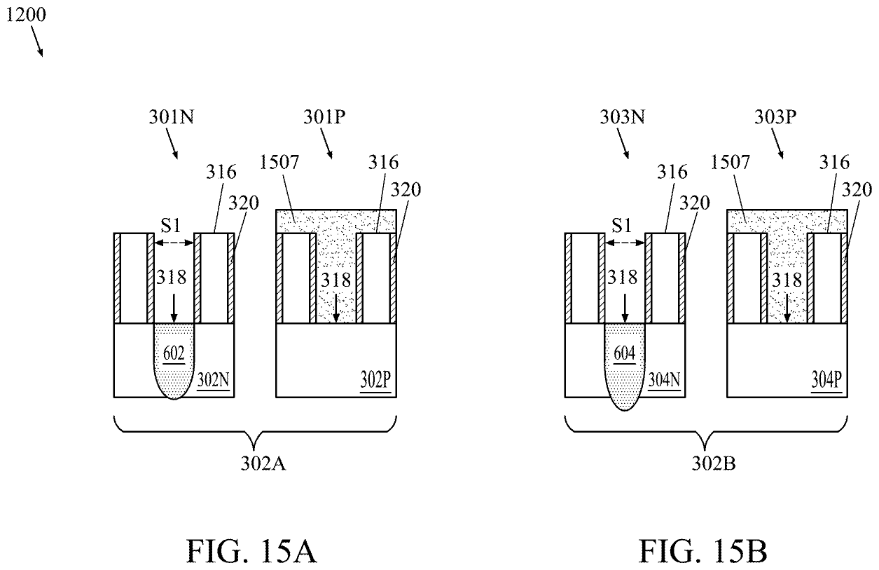

The method 1100 then proceeds to block 1108 where N-type source/drain features are formed. Referring to FIGS. 15A, 15B, in an embodiment of block 1108, N-type source/drain features 602 are formed in the source/drain recess 402 of the N-type SRAM device 301N, and N-type source/drain features 604 are formed in the source/drain recess 502 of the N-type SOC logic device 303N. In some embodiments, the source/drain features 602, 604 are formed in the source/drain regions 318 adjacent to and on either side of the gate stacks 316 of each of the N-type SRAM device 301N and the N-type SOC logic device 303N. In some embodiments, a clean process may be performed immediately prior to formation of the source/drain features 602, 604. The clean process may include a wet etch, a dry etch, or a combination thereof.

In some examples, prior to forming the N-type source/drain features 602, 604, a mask layer may be deposited and patterned to form a patterned mask layer 1507 having openings which expose the N-type SRAM device 301N and the N-type SOC logic device 303N, while the P-type SRAM device 301P and the P-type SOC logic device 303P remain protected by the patterned mask layer 1507. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1507 may include a patterned resist layer and/or a patterned hard mask layer, as described above. In some embodiments, the openings in the patterned mask layer 1507 which expose the N-type SRAM device 301N and the N-type SOC logic device 303N may be formed using a high-grade photomask and a lithography system with high resolution, as discussed above. Whether or not a hard mask layer is used, and after exposure of the N-type SRAM device 301N and the N-type SOC logic device 303N, the N-type source/drain features 602, 604 may be formed. After formation of the N-type source/drain features 602, 604, the patterned mask layer 1507 is removed (e.g., such as by using an appropriate etchant, solvent, or ashing process). In various embodiments, the source/drain features 602, 604 are epitaxially grown and may be substantially the same as described above with reference to block 208 of the method 200. In some cases, the source/drain features 602, 604 may also extend above a top surface of their respective fins 302N, 304N, being referred to as raised source/drain features. In accordance with the embodiments disclosed herein, the N-type source/drain features 602, 604 are thus effectively co-optimized for the N-type SRAM device 301N and the N-type SOC logic device 303N.

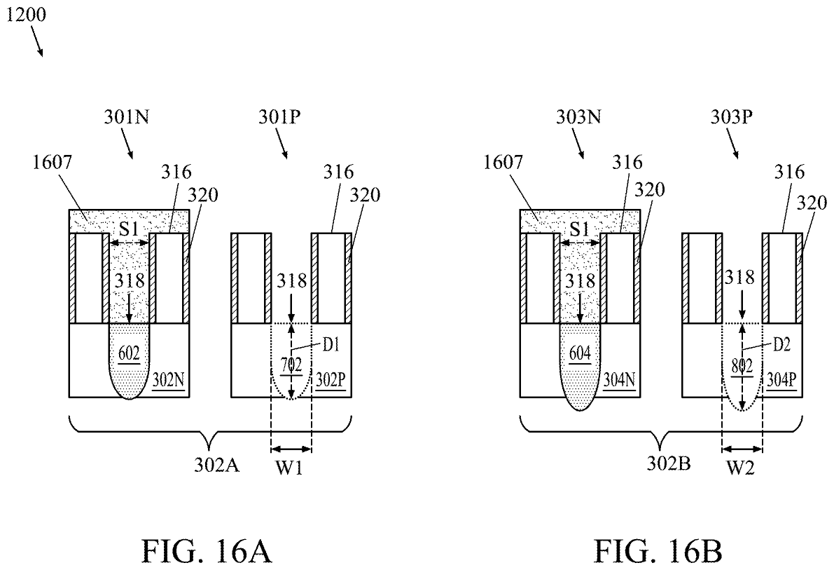

The method 1100 proceeds to block 1110 where a photo/etch process for P-type S/D regions is performed. Referring to the example of FIGS. 16A, 16B, in an embodiment of block 1110, a photo/etch process is performed to simultaneously form a source/drain recess 702 within the source/drain region 318 of the P-type SRAM device 301P and a source/drain recess 802 within the source/drain region 318 of the P-type SOC logic device 303P. Initially, a mask layer may be deposited and patterned to form a patterned mask layer 1607 having openings which expose the P-type SRAM device 301P and the P-type SOC logic device 303P while the N-type SRAM device 301N and the N-type SOC logic device 303N remain protected by the patterned mask layer 1607. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1607 may include a patterned resist layer and/or a patterned hard mask layer, as previously described. In some embodiments, the openings in the patterned mask layer 1607 which expose the P-type SRAM device 301P and the P-type SOC logic device 303P may be formed using a high-grade photomask and a lithography system with high resolution, for example, due to the smaller dimensions of the openings formed in the patterned mask layer 1607. Whether or not a hard mask layer is used, and after exposure of the P-type SRAM device 301P and the P-type SOC logic device 303P, an etching process (e.g., wet etch, dry etch, or combination thereof) is performed to remove portions of the fins 302P, 304P in the source/drain region 318 of the P-type SRAM device 301P and the P-type SOC logic device 303P to form the source/drain recesses 702, 802. In some embodiments, the source/drain etching process is a dry etch using an etchant that includes a chlorine-containing gas, a fluorine-containing gas or both, such as Cl₂, CCl₂F₂, SF₆, or a combination thereof. After formation of the source/drain recesses 702, 802, the patterned mask layer 1607 is removed (e.g., such as by using an appropriate etchant, solvent, or ashing process).

As shown in FIGS. 16A and 16B, the source/drain recess 702 is etched to the depth D1 and the width W1, similar to the depth and width of the source/drain recess 402 formed in the N-type SRAM device 301N, and the source/drain recess 802 is etched to the depth D2 and the width W2, similar to the depth and width of the source/drain recess 502 formed in the N-type SOC logic device 303N. Due to the ion implantation process, and the associated increased etch rate of the source/drain region 318 of the P-type SOC logic device 303P, the depth D2 of the source/drain recess 802 of the P-type SOC logic device 303P is greater than (deeper than) the depth D1 of the source/drain recess 702 of the P-type SRAM device 301P, thereby simultaneously providing tighter control of SCEs for the P-type SRAM device 301P and higher current/performance for the P-type SOC logic device 303P. Even though the recesses 702, 802 may be formed simultaneously, the varied etch rate of the source/drain regions 318 provided by the ion implantation process nevertheless ensures that the S/D depth of each of the P-type SRAM device 301P and the P-type SOC logic device 303P can be independently controlled and optimized (e.g., by controlling process parameters of the ion implantation process).

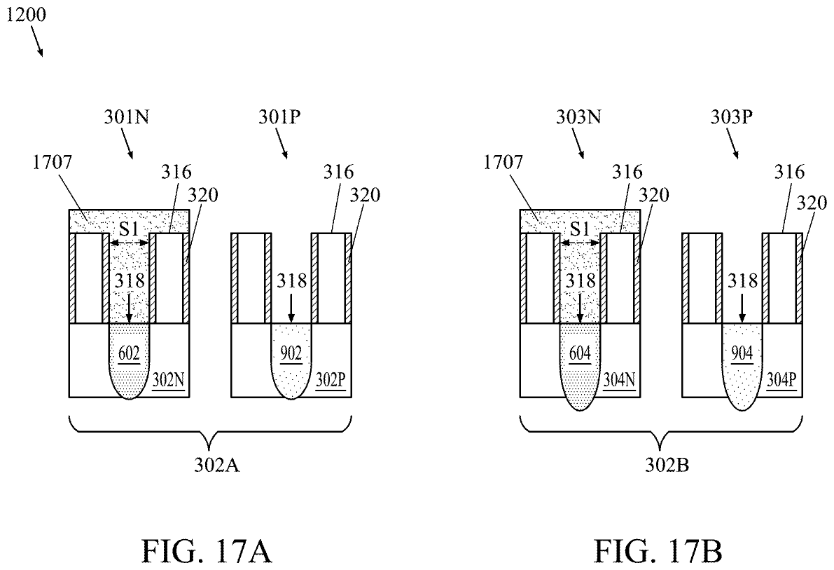

The method 1100 then proceeds to block 1112 where P-type source/drain features are formed. Referring to FIGS. 17A, 17B, in an embodiment of block 1112, P-type source/drain features 902 are formed in the source/drain recess 702 of the P-type SRAM device 301P, and P-type source/drain features 904 are formed in the source/drain recess 802 of the P-type SOC logic device 303P. In some embodiments, the source/drain features 902, 904 are formed in the source/drain regions 318 adjacent to and on either side of the gate stacks 316 of each of the P-type SRAM device 301P and the P-type SOC logic device 303P. In some embodiments, a clean process may be performed immediately prior to formation of the source/drain features 902, 904. The clean process may include a wet etch, a dry etch, or a combination thereof.

In some examples, prior to forming the P-type source/drain features 902, 904, a mask layer may be deposited and patterned to form a patterned mask layer 1707 having openings which expose the P-type SRAM device 301P and the P-type SOC logic device 303P, while the N-type SRAM device 301N and the N-type SOC logic device 303N remain protected by the patterned mask layer 1707. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1707 may include a patterned resist layer and/or a patterned hard mask layer, as described above. In some embodiments, the openings in the patterned mask layer 1707 which expose the P-type SRAM device 301P and the P-type SOC logic device 303P may be formed using a high-grade photomask and a lithography system with high resolution, as discussed above. Whether or not a hard mask layer is used, and after exposure of the P-type SRAM device 301P and the P-type SOC logic device 303P, the P-type source/drain features 902, 904 may be formed. After formation of the P-type source/drain features 902, 904, the patterned mask layer 1707 is removed (e.g., such as by using an appropriate etchant, solvent, or ashing process). In various embodiments, the source/drain features 902, 904 are epitaxially grown and may be substantially the same as described above with reference to block 214 of the method 200. In some cases, the source/drain features 902, 904 may also extend above a top surface of their respective fins 302P, 304P, being referred to as raised source/drain features. In accordance with the embodiments disclosed herein, the P-type source/drain features 902, 904 are thus effectively co-optimized for the P-type SRAM device 301P and the P-type SOC logic device 303P.

The method 1100 then proceeds to block 1114 where further processing is performed, as described above. This may include, for example, formation of a CESL and an ILD layer over the device 1200, followed by a CMP process. The further processing of block 1114 further includes removal of the dummy gates (e.g., the gate stacks 316), and formation of a gate structure over the N-type and P-type devices within each of the regions 302A, 302B. The gate structure may include a high-K/metal gate stack, as discussed above, however other compositions are possible. In various embodiments, the gate structure may form the gate associated with each of the N-type and P-type SRAM devices 301N, 301P and the N-type and P-type SOC logic devices 303N, 303P.

Generally, the semiconductor device 1200 may undergo further processing to form various features and regions known in the art. For example, further processing may form various contacts/vias/lines and multilayer interconnect features (e.g., metal layers and interlayer dielectrics) on the substrate, configured to connect the various features to form a functional circuit that may include one or more multi-gate devices (e.g., FinFET devices). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 1100, and some process steps described above may be modified, replaced, or eliminated in accordance with various embodiments of the method 1100.

For example, while the method 1100 has been described as first forming the N-type source/drain regions and then the P-type source/drain regions, it will be understood that is some cases the P-type source/drain regions may be formed before the N-type source/drain regions. Further, while the method 1100 was described as performing an ion implantation process into the source/drain regions 318 of both the N-type SOC logic device 303N and the P-type SOC logic device 303P, other embodiments are possible. For instance, in some embodiments, the ion implantation process may be performed into only one of the source/drain regions 318 of the N-type SOC logic device 303N and the P-type SOC logic device 303P. As a result, the etch rate of the source/drain regions 318 of only one of the N-type SOC logic device 303N and the P-type SOC logic device 303P will be increased. Thus, in this example, only one of the N-type source/drain regions or the P-type source/drain regions for the various device types (e.g., the SRAM and SOC logic devices) may have different depths.

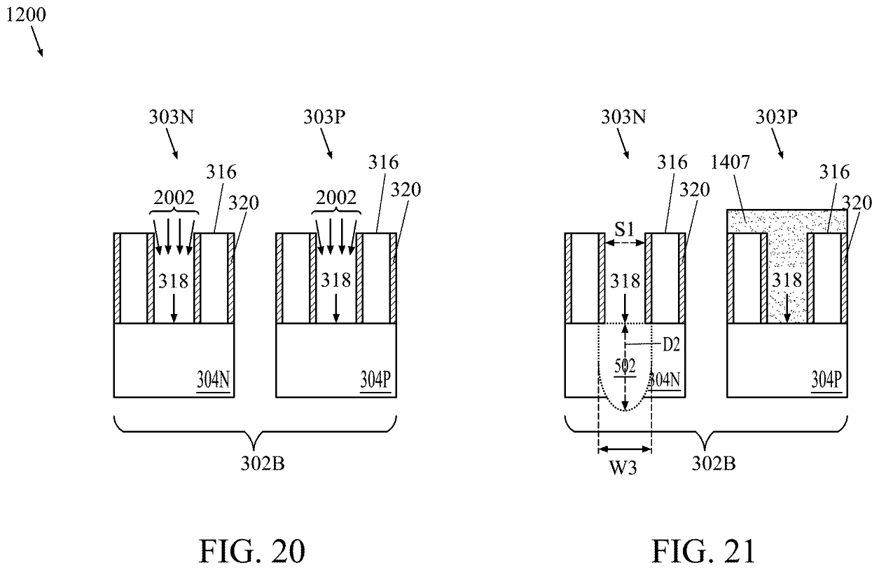

In another embodiment, the ion implantation process of block 1104 may be modified such that the implantation process is performed multiple times, where at least one of the implantations is performed at a non-zero-degree tilt angle. This example is described below with reference to FIGS. 20, 21, 22, 23, and 24, which effectively replace FIGS. 13B, 14B, 15B, 16B, and 17B, respectively, in the method 1100 when at least one of the ion implantations of block 1104 is performed at a non-zero-degree tilt angle. Referring to the example of FIG. 20, in an embodiment of block 1104, a plurality of ion implantation processes 2002 are performed into the source/drain regions 318 of the N-type SOC logic device 303N and the P-type SOC logic device 303P. In the illustrated example, the ion implantation processes 2002 are performed at a plurality of angles including, for example, one or more non-zero-degree tilt angles, as well as a zero-degree tilt angle (e.g., substantially perpendicular to the substrate).

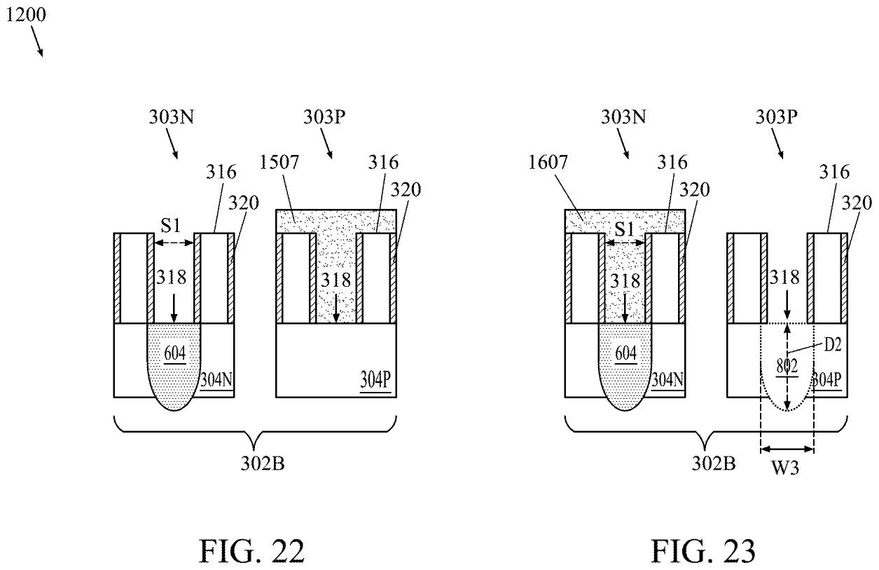

Referring to the FIG. 21, in an embodiment of block 1106, the source/drain recess 502 is etched to the depth D2 and the width W3. Due to the ion implantation process, including the one or more non-zero-degree tilt angle implants and the associated increased etch rate of the source/drain region 318 of the N-type SOC logic device 303N, both the width W3 and the depth D2 of the source/drain recess 502 of the N-type SOC logic device 303N are greater than (deeper than and wider than) the depth D1 and the width W1 of the source/drain recess 402 of the N-type SRAM device 301N. Further, the width W3 of the source/drain recess 502 formed as a result of using the one or more non-zero-degree tilt angle implants is greater than (wider than) the width W2 of the source/drain recess 502 when only a zero-degree tilt angle is used. Referring to the FIG. 22, in an embodiment of block 1108, N-type source/drain features 604 are formed in the (deeper and wider) source/drain recess 502 of the N-type SOC logic device 303N.

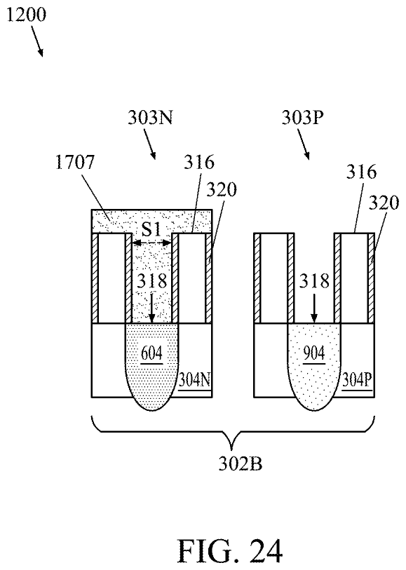

Referring to the FIG. 23, in an embodiment of block 1110, the source/drain recess 802 is etched to the depth D2 and the width W3. Due to the ion implantation process, including the one or more non-zero-degree tilt angle implants and the associated increased etch rate of the source/drain region 318 of the P-type SOC logic device 303P, both the width W3 and the depth D2 of the source/drain recess 802 of the P-type SOC logic device 303P are greater than (deeper than and wider than) the depth D1 and the width W1 of the source/drain recess 702 of the P-type SRAM device 301P. Further, the width W3 of the source/drain recess 802 formed as a result of using the one or more non-zero-degree tilt angle implants is greater than (wider than) the width W2 of the source/drain recess 802 when only a zero-degree tilt angle is used. Referring to the FIG. 24, in an embodiment of block 1112, P-type source/drain features 904 are formed in the (deeper and wider) source/drain recess 802 of the P-type SOC logic device 303P.

While various exemplary modifications to the method 1100 have been discussed, it will be understood that the above examples are merely illustrative and not meant to be limiting. Those of skill in the art, having the benefit of the present disclosure, will understand that yet other embodiments and/or modifications are possible, without departing from the scope of this disclosure.

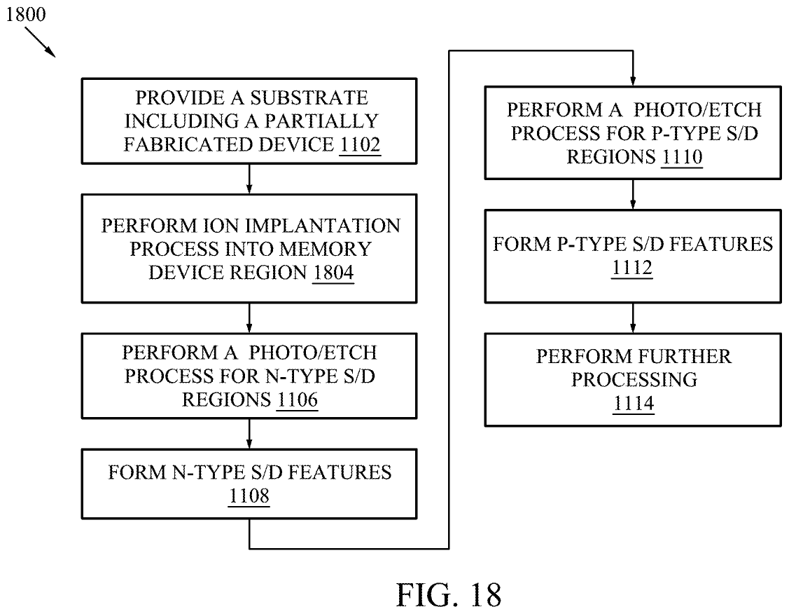

Referring now to FIG. 18, illustrated therein is an alternative method 1800 of semiconductor fabrication including fabrication of the semiconductor device 1200, discussed above with reference to the method 1100. The method 1800 is substantially the same as the method 1100, except for the ion implantation process step. Therefore, for simplicity of discussion, the steps of the method 1800 that are the same as those of the method 1100 are not repeated here. With respect to the ion implantation process, block 1104 of the method 1100 described implanting a dopant species into a logic device region (e.g., including the N-type SOC logic device 303N and the P-type SOC logic device 303P) to increase the etch rate of the source/drain regions 318 in the logic device region. In the method 1800, block 1104 is replaced with block 1804, where a dopant species is implanted into a memory device region (e.g., including the N-type SRAM device 301N and the P-type SRAM device 301P) to decrease the etch rate of the source/drain regions 318 in the memory device region.

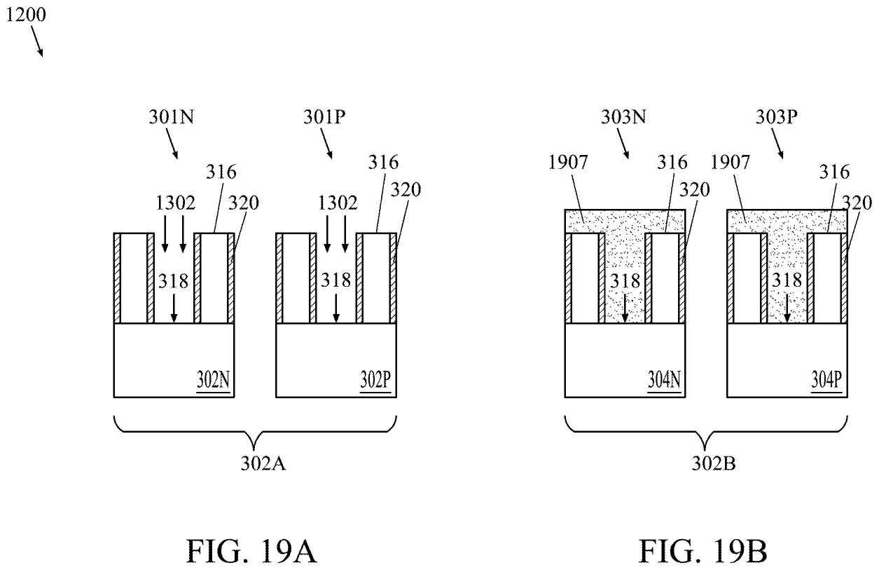

An embodiment of the block 1804 of the method 1800 is described below with reference to FIGS. 19A/19B, which provide cross-sectional views of embodiments of the device 1200 along a plane substantially parallel to a plane defined by section AA′ of FIG. 1. As shown in FIGS. 19A/19B, an ion implantation process is performed into the source/drain regions 318 of the N-type SRAM device 301N and the P-type SRAM device 301P. Initially, a mask layer may be deposited and patterned to form a patterned mask layer 1907 having an opening which exposes the N-type SRAM device 301N and the P-type SRAM device 301P, while the N-type SOC logic device 303N and the P-type SOC logic device 303P remain protected by the patterned mask layer 1907. In some embodiments, the mask layer includes a resist layer and/or a hard mask layer (e.g., silicon oxide, silicon nitride, silicon oxynitride, silicon carbide, or other appropriate hard mask layer) such that the patterned mask layer 1907 may include a patterned resist layer and/or a patterned hard mask layer, as previously discussed. In some examples, and due to the larger dimensions of the opening formed in the patterned mask layer 1907 to expose both the N-type SRAM device 301N and the P-type SRAM device 301P, formation of the patterned mask layer 1907 may include use of a low-grade photomask and a lithography system with low resolution, as compared to the high-grade photomask and lithography system with high resolution, discussed above.

Whether or not a hard mask layer is used, and after exposure of the N-type SRAM device 301N and the P-type SRAM device 301P, an ion implantation process is performed to introduce a dopant species into the source/drain regions 318 of the N-type SRAM device 301N and the P-type SRAM device 301P. The dopant species is introduced into the source/drain regions 318 but not into the channels (portions of the fins underlying the gate stacks 316) since the channels remain covered by the gate stacks 316. In some embodiments, the dopant species includes at least one of boron (B), boron sulfide (BS₂), difluoroboron (BF₂), boron trifluoride (BF₃), and a combination thereof. In some cases, the implantation process is performed at an angle that is substantially perpendicular to the substrate (e.g., at a tilt angle of about zero degrees), although other implant angles are possible. In some embodiments, the ion implantation process is performed through the portion of the one or more spacer layers 320 or the separately formed dielectric layer, if present, between the gate stacks 316 and over the source/drain regions 318. The purpose of implanting the dopant species into the source/drain regions 318 is to modify the etch rate of the source/drain regions 318 during a subsequent etching process to recess the source/drain regions 318 (blocks 1106 and 1110). In the present example, the etch rate of the implanted source/drain regions 318 of the N-type SRAM device 301N and the P-type SRAM device 301P is decreased. In some cases, the decreased etch rate is due to a chemical reaction that occurs between the implanted dopant species and the etchant used to recess the source/drain regions 318 (blocks 1106 and 1110), thereby decreasing the etch rate of the implanted regions. In some embodiments, the doping concentration of the implanted dopant species ranges between 1×10¹⁹ and 1×10²² (cm³). The corresponding implantation dose ranges between 1×10¹⁴ and 1×10¹⁶ (cm²). In addition, the ion implantation process includes a bias power ranging between 1K eV and 4K eV to provide the intended etch rate variation. After performing the ion implantation process, the patterned mask layer 1907 is removed (e.g., such as by using an appropriate etchant, solvent, or ashing process).

Due to the ion implantation process, and the associated decreased etch rate of the source/drain region 318 of the N-type SRAM device 301N, the depth D1 of the source/drain recess 402 of the N-type SRAM device 301N will be less than (shallower than) the depth D2 of the source/drain recess 502 of the N-type SOC logic device 303N, thereby providing tighter control of SCEs for the N-type SRAM device 301N and higher current/performance for the N-type SOC logic device 303N. Similarly, due to the ion implantation process, and the associated decreased etch rate of the source/drain region 318 of the P-type SRAM device 301P, the depth D1 of the source/drain recess 702 of the P-type SRAM device 301P will be less than (shallower than) the depth D2 of the source/drain recess 802 of the P-type SOC logic device 303P, thereby providing tighter control of SCEs for the P-type SRAM device 301P and higher current/performance for the P-type SOC logic device 303P.

It is also noted that while the method 1800 was described as performing an ion implantation process into the source/drain regions 318 of both the N-type SRAM device 301N and the P-type SRAM device 301P, other embodiments are possible. For instance, in some embodiments, the ion implantation process may be performed into only one of the source/drain regions 318 of the N-type SRAM device 301N and the P-type SRAM device 301P. As a result, the etch rate of the source/drain regions 318 of only one of the N-type SRAM device 301N and the P-type SRAM device 301P will be decreased. Thus, in this example, only one of the N-type source/drain regions or the P-type source/drain regions for the various device types (e.g., the SRAM and SOC logic devices) may have different depths. While some exemplary modifications to the method 1800 have been discussed, it will be understood that these examples are merely illustrative and not meant to be limiting. Those of skill in the art, having the benefit of the present disclosure, will understand that yet other embodiments and/or modifications are possible, without departing from the scope of this disclosure.

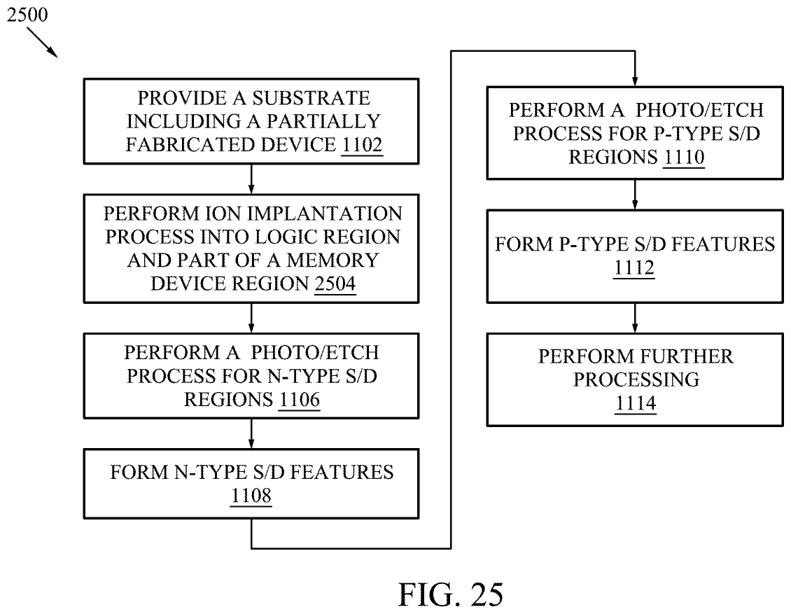

Referring now to FIG. 25, illustrated therein is an alternative method 2500 of semiconductor fabrication including fabrication of the semiconductor device 1200, discussed above with reference to the method 1100. The method 2500 is substantially the same as the method 1100, except for the ion implantation process step. Therefore, for simplicity of discussion, the steps of the method 2500 that are the same as those of the method 1100 are not repeated here. With respect to the ion implantation process, block 1104 of the method 1100 described implanting a dopant species into a logic device region (e.g., including the N-type SOC logic device 303N and the P-type SOC logic device 303P) to increase the etch rate of the source/drain regions 318 in the logic device region. In the method 2500, block 1104 is replaced with block 2504, where a dopant species is implanted into the logic device region (e.g., including the N-type SOC logic device 303N and the P-type SOC logic device 303P) and into part of the memory device region (e.g., one of the N-type SRAM device 301N and the P-type SRAM device 301P) to increase the etch rate of the source/drain regions 318 in the logic device region and in part of the memory device region. While the example below is described as implanting a dopant species into the P-type SRAM device 301P (and not the N-type SRAM device 301N), it will be understood that in some cases, a dopant species may instead by implanted into the N-type SRAM device 301N (and not the P-type SRAM device 301P).

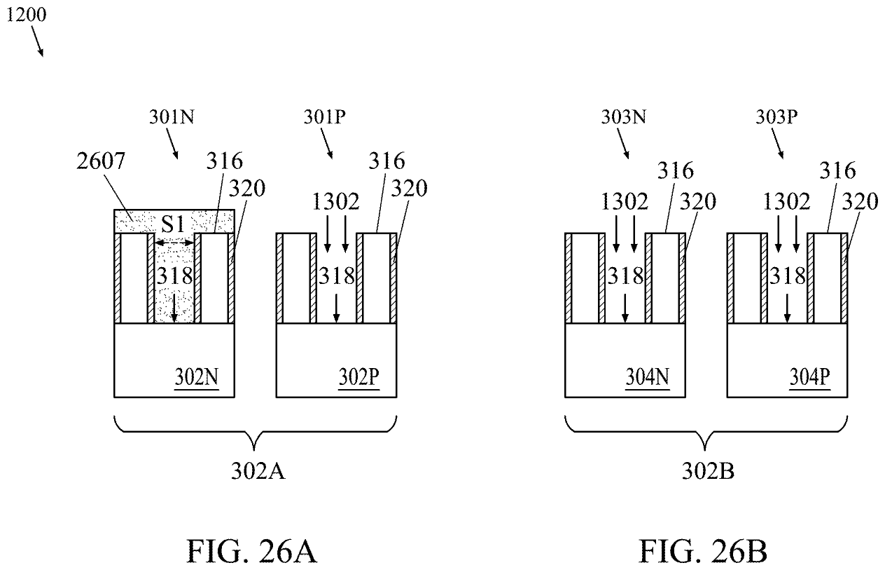

An embodiment of the block 2504 of the method 2500 is described below with reference to FIGS. 26A/26B, which provide cross-sectional views of embodiments of the device 1200 along a plane substantially parallel to a plane defined by section AA′ of FIG. 1. As shown in FIGS. 26A/26B, an ion implantation process is performed into the source/drain regions 318 of the P-type SRAM device 301P, and the N-type and P-type SOC logic devices 303N, 303P. Initially, a mask layer may be deposited and patterned to form a patterned mask layer 2607 having an opening which exposes the P-type SRAM device 301P, and the N-type and P-type SOC logic devices 303N, 303P, while the N-type SRAM device 301N remains protected by the patterned mask layer 2607. In some embodiments, the mask layer includes a resist layer and/or a hard mask layer (e.g., silicon oxide, silicon nitride, silicon oxynitride, silicon carbide, or other appropriate hard mask layer) such that the patterned mask layer 2607 may include a patterned resist layer and/or a patterned hard mask layer, as previously discussed. In some examples, and due to the larger dimensions of the opening formed in the patterned mask layer 2607 to expose the P-type SRAM device 301P, and the N-type and P-type SOC logic devices 303N, 303P, formation of the patterned mask layer 2607 may include use of a low-grade photomask and a lithography system with low resolution, as compared to the high-grade photomask and lithography system with high resolution, discussed above.

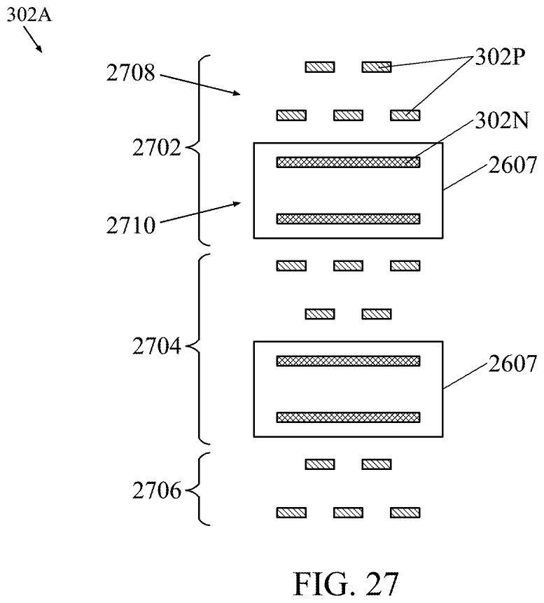

For purposes of illustration, FIG. 27 illustrates a top-down view of the region 302A of the substrate including SRAM cells (or portions thereof) 2702, 2704, 2706 after formation of the patterned mask layer 2607. In some embodiments, the SRAM cells 2702, 2704, 2706 may include a pull-up region 2708 and a pull-down/pass-gate region 2710. The pull-up region 2708 includes the P-type SRAM devices 301P including a plurality of P-type fins 302P, and the pull-down region 2710 includes the N-type SRAM devices 301N including a plurality of N-type fins 302N. As shown, the patterned mask layer 2607 exposes the P-type SRAM devices 301P including the plurality of P-type fins 302P, while the N-type SRAM devices 301N including a plurality of N-type fins 302N remain protected by the patterned mask layer 2607. In some cases, the SRAM cells 2702, 2704, 2706 may include high-density SRAM cells.

Whether or not a hard mask layer is used, and after exposure of the P-type SRAM device 301P, and the N-type and P-type SOC logic devices 303N, 303P, an ion implantation process is performed to introduce a dopant species into the source/drain regions 318 of the P-type SRAM device 301P, and the N-type and P-type SOC logic devices 303N, 303P. The dopant species is introduced into the source/drain regions 318 but not into the channels (portions of the fins underlying the gate stacks 316) since the channels remain covered by the gate stacks 316. In some embodiments, the dopant species includes at least one of carbon (C), silicon (Si), germanium (Ge), hydrogen (H), nitrogen (N), fluorine (F), argon (Ar), and a combination thereof. Alternatively, or additionally, the dopant species includes at least one of gallium (Ga), phosphorous (P), arsenic (As), and a combination thereof. In some cases, the implantation process is performed at an angle that is substantially perpendicular to the substrate (e.g., at a tilt angle of about zero degrees), although other implant angles are possible. In some embodiments, the ion implantation process is performed through the portion of the one or more spacer layers 320 or the separately formed dielectric layer, if present, between the gate stacks 316 and over the source/drain regions 318. The purpose of implanting the dopant species into the source/drain regions 318 is to modify the etch rate of the source/drain regions 318 during a subsequent etching process to recess the source/drain regions 318 (blocks 1106 and 1110). In the present example, the etch rate of the implanted source/drain regions 318 of the P-type SRAM device 301P, and the N-type and P-type SOC logic devices 303N, 303P is increased. In some cases, the increased etch rate is due to damage to the source/drain regions 318 caused by the implanted dopant ions, which cause structural changes (e.g., such as defect formation) and accordingly increase the etch rate of the implanted regions. In some embodiments, the doping concentration of the implanted dopant species ranges between 1×10¹⁹ and 1×10²² (cm³). The corresponding implantation dose ranges between 1×10¹⁴ and 1×10¹⁶ (cm²). In addition, the ion implantation process includes a bias power ranging between 1K eV and 4K eV to provide the intended damage and etch rate variation. After performing the ion implantation process, the patterned mask layer 2607 is removed (e.g., such as by using an appropriate etchant, solvent, or ashing process).

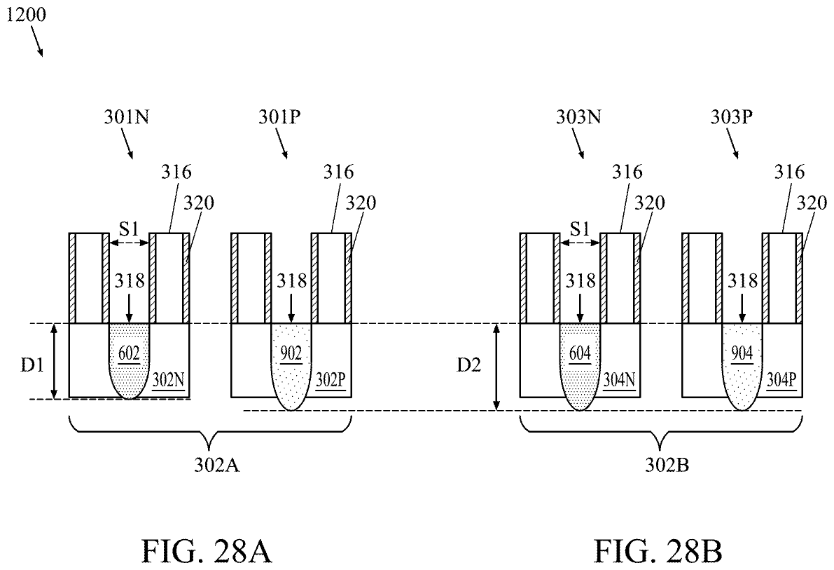

Due to the ion implantation process, and the associated increased etch rate of the source/drain region 318 of the P-type SRAM device 301P, and the N-type and P-type SOC logic devices 303N, 303P, each of the source/drain recesses 502 (of the N-type SOC logic device 303N), 702 (of the P-type SRAM device 301P), and 802 (of the P-type SOC logic device 303P) is etched to the deeper depth D2, described above. Thus, the depth D2 of the source/drain recesses 502, 702, 802 of the P-type SRAM device 301P, and the N-type and P-type SOC logic devices 303N, 303P will be greater than (deeper than) the depth D1 of the source/drain recess 402 of the N-type SRAM device 301N. By way of example, FIGS. 28A/28B illustrate a final structure of the device 1200 fabricated according to the method 2500. As shown, only the N-type devices (N-type SRAM device 301N, N-type SOC logic device 303N) have different depths D1, D2 of the source/drain features 602, 604, respectively. The P-type devices (P-type SRAM device 301P, P-type SOC logic device 303P) have the same depth D2 of the source/drain features 902, 904. In the present example, the P-type SRAM device 301P also has the same depth D2 as both of the N-type SOC logic device 303N and the P-type SOC logic device 303P.

It is also noted that while the method 2500 was described as implanting a dopant species into the P-type SRAM device 301P (and not the N-type SRAM device 301N), in some cases a dopant species may instead by implanted into the N-type SRAM device 301N (and not the P-type SRAM device 301P). In such an example, only the P-type devices (P-type SRAM device 301P, P-type SOC logic device 303P) will have different depths D1, D2 of the source/drain features 902, 904, respectively, while the N-type devices (N-type SRAM device 301N, N-type SOC logic device 303N) have the same depth D2 of the source/drain features 602, 604. Thus, in this example, the N-type SRAM device 301N would also have the same depth D2 as both of the N-type SOC logic device 303N and the P-type SOC logic device 303P. While some exemplary modifications to the method 2500 have been discussed, it will be understood that these examples are merely illustrative and not meant to be limiting. Those of skill in the art, having the benefit of the present disclosure, will understand that yet other embodiments and/or modifications are possible, without departing from the scope of this disclosure.

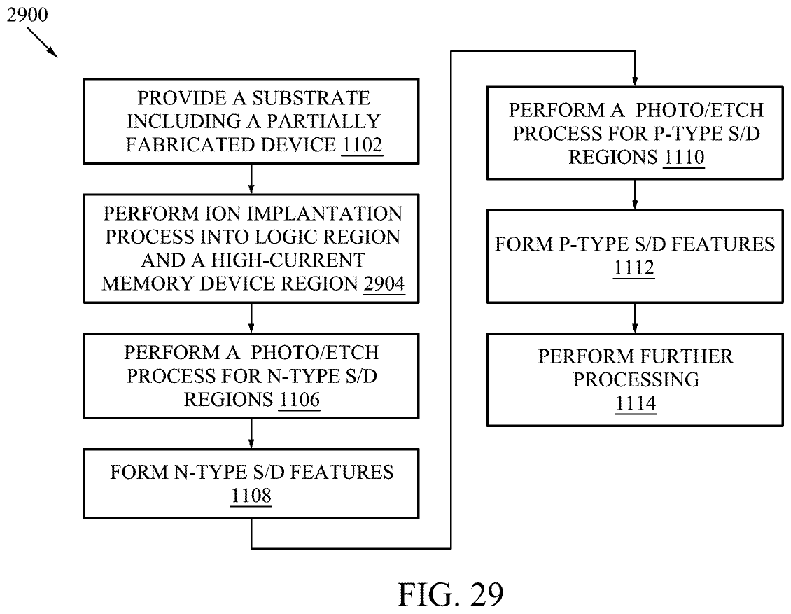

With reference to FIG. 29, illustrated therein is another method 2900 of semiconductor fabrication including fabrication of the semiconductor device 1200, discussed above with reference to the method 1100. The method 2900 is similar to the method 1100, except for the ion implantation process step and the disclosure of two different types of SRAM devices (high-density SRAM and high-current SRAM). Therefore, for simplicity of discussion, the steps of the method 2900 that are the same as those of the method 1100 are not repeated here. It is also noted that in at least some embodiments, the SRAM devices discussed above (N-type and P-type SRAM devices 301N, 301P) may include the high-density SRAM devices or high-current SRAM devices discussed below. With respect to the ion implantation process, block 1104 of the method 1100 described implanting a dopant species into a logic device region (e.g., including the N-type SOC logic device 303N and the P-type SOC logic device 303P) to increase the etch rate of the source/drain regions 318 in the logic device region. In the method 2900, block 1104 is replaced with block 2904, where a dopant species is implanted into the logic device region (e.g., including the N-type SOC logic device 303N and the P-type SOC logic device 303P) and into a high-current SRAM (SRAM-HC) device region (e.g., which includes an N-type SRAM-HC device 301N-2 and a P-type SRAM-HC device 301P-2) to increase the etch rate of the source/drain regions 318 in the logic device region and in the SRAM-HC device region. While the example below is described as implanting a dopant species into both of the N-type SRAM-HC device 301N-2 and the P-type SRAM-HC device 301P-2, it will be understood that in some cases, a dopant species may instead by implanted into only one of the N-type SRAM-HC device 301N-2 and the P-type SRAM-HC device 301P-2.

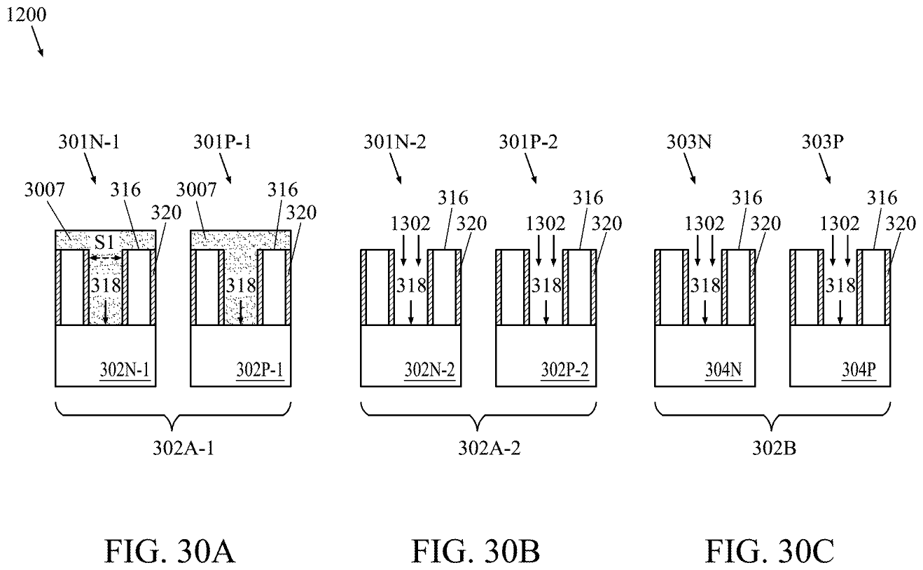

An embodiment of the block 2904 of the method 2900 is described below with reference to FIGS. 30A/30B/30C, which provide cross-sectional views of embodiments of the device 1200 along a plane substantially parallel to a plane defined by section AA′ of FIG. 1. As shown in FIGS. 30A/30B/30C, an ion implantation process is performed into the source/drain regions 318 of the N-type SRAM-HC device 301N-2 and the P-type SRAM-HC device 301P-2, and the N-type and P-type SOC logic devices 303N, 303P. Initially, a mask layer may be deposited and patterned to form a patterned mask layer 3007 having an opening which exposes the N-type and P-type SRAM-HC devices 301N-2, 301P-2 and the N-type and P-type SOC logic devices 303N, 303P, while a high-density SRAM (SRAM-HD) device region (e.g., which includes an N-type SRAM-HD device 301N-1 and a P-type SRAM-HD device 301P-1) remains protected by the patterned mask layer 3007. In some embodiments, the mask layer includes a resist layer and/or a hard mask layer (e.g., silicon oxide, silicon nitride, silicon oxynitride, silicon carbide, or other appropriate hard mask layer) such that the patterned mask layer 3007 may include a patterned resist layer and/or a patterned hard mask layer, as previously discussed. In some examples, and due to the larger dimensions of the opening formed in the patterned mask layer 3007 to expose the N-type and P-type SRAM-HC devices 301N-2, 301P-2 and the N-type and P-type SOC logic devices 303N, 303P, formation of the patterned mask layer 3007 may include use of a low-grade photomask and a lithography system with low resolution, as compared to the high-grade photomask and lithography system with high resolution, discussed above.

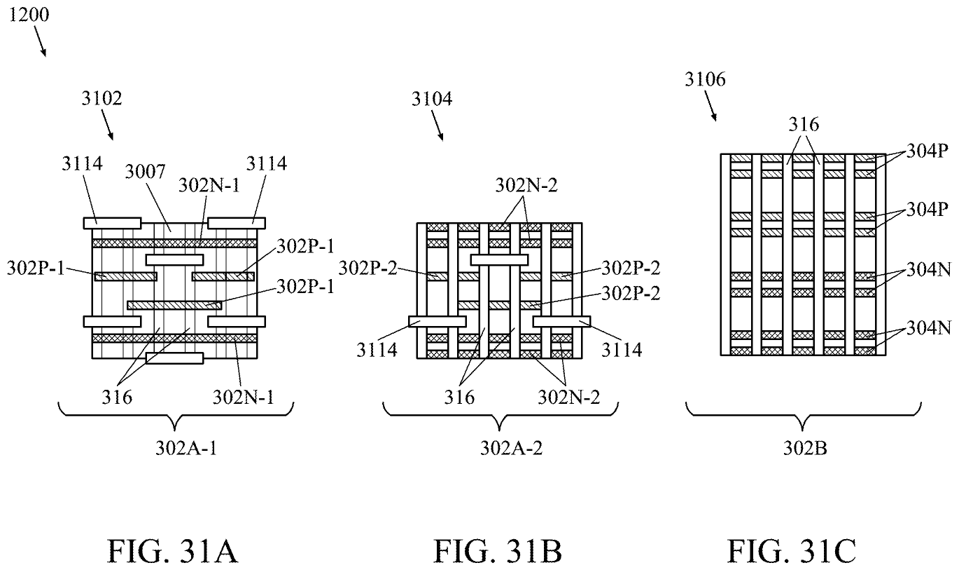

For purposes of illustration, FIGS. 31A/31B/31C illustrate top-down views of regions 302A-1, 302A-2, 302B of the substrate, which respectively include an SRAM-HD cell (or portion thereof) 3102, an SRAM-HC cell (or portion thereof) 3104, and an SOC logic cell (or portion thereof) 3106 after formation of the patterned mask layer 3007. In some embodiments, the SRAM-HD cell 3102 includes the P-type SRAM-HD devices 301P-1 including a plurality of P-type fins 302P-1 and the N-type SRAM-HD devices 301N-1 including a plurality of N-type fins 302N-1. The P-type SRAM-HD devices 301P-1 may form a pull-up region of the SRAM HD cell 3102, and the N-type SRAM-HD devices 301N-1 may form a pull-down/pass-gate region of the SRAM HD cell 3102. In some examples, the SRAM-HC cell 3104 includes the P-type SRAM-HC devices 301P-2 including a plurality of P-type fins 302P-2 and the N-type SRAM-HC devices 301N-2 including a plurality of N-type fins 302N-2. The P-type SRAM-HC devices 301P-2 may form a pull-up region of the SRAM HC cell 3104, and the N-type SRAM-HC devices 301N-2 may form a pull-down/pass-gate region of the SRAM HC cell 3104. The SOC logic cell 3106 is composed of the N-type SOC logic devices 303N including a plurality of N-type fins 304N and P-type SOC logic devices 303P including a plurality of P-type fins 304P. Each of the SRAM-HD cell 3102, the SRAM-HC cell 3104, and the SOC logic cell 3106 also illustrate the gate stacks 316 formed over respective fins 302N-1, 302P-1, 302N-2, 302P-2, 304N, 304P within each of the regions 302A-1, 302A-2, 302B. The top-down views of the regions 302A-1, 302A-2 also illustrate cut gate isolation regions 3114, which define regions where the gate stacks 316 are cut to form multiple, adjacent gate stacks 316 that are electrically isolated from each other by a dielectric layer formed in the cut gate isolation regions 3114. As shown, the patterned mask layer 3007 exposes the N-type and P-type SRAM-HC devices 301N-2, 301P-2 including the plurality of fins 302N-2, 302P-2 and the N-type and P-type SOC logic devices 303N, 303P including the plurality of fins 304N, 304P, while the N-type and P-type SRAM-HD devices 301N-1, 301P-1 including the plurality of fins 302N-1, 302P-1 remain protected by the patterned mask layer 3007.

Whether or not a hard mask layer is used, and after exposure of the N-type and P-type SRAM-HC devices 301N-2, 301P-2 and the N-type and P-type SOC logic devices 303N, 303P, an ion implantation process is performed to introduce a dopant species into the source/drain regions 318 of the N-type and P-type SRAM-HC devices 301N-2, 301P-2 and the N-type and P-type SOC logic devices 303N, 303P. The dopant species is introduced into the source/drain regions 318 but not into the channels (portions of the fins underlying the gate stacks 316) since the channels remain covered by the gate stacks 316. In some embodiments, the dopant species includes at least one of carbon (C), silicon (Si), germanium (Ge), hydrogen (H), nitrogen (N), fluorine (F), argon (Ar), and a combination thereof. Alternatively, or additionally, the dopant species includes at least one of gallium (Ga), phosphorous (P), arsenic (As), and a combination thereof. In some cases, the implantation process is performed at an angle that is substantially perpendicular to the substrate (e.g., at a tilt angle of about zero degrees), although other implant angles are possible. In some embodiments, the ion implantation process is performed through the portion of the one or more spacer layers 320 or the separately formed dielectric layer, if present, between the gate stacks 316 and over the source/drain regions 318. The purpose of implanting the dopant species into the source/drain regions 318 is to modify the etch rate of the source/drain regions 318 during a subsequent etching process to recess the source/drain regions 318 (blocks 1106 and 1110). In the present example, the etch rate of the implanted source/drain regions 318 of the N-type and P-type SRAM-HC devices 301N-2, 301P-2 and the N-type and P-type SOC logic devices 303N, 303P is increased. In some cases, the increased etch rate is due to damage to the source/drain regions 318 caused by the implanted dopant ions, which cause structural changes (e.g., such as defect formation) and accordingly increase the etch rate of the implanted regions. In some embodiments, the doping concentration of the implanted dopant species ranges between 1×10¹⁹ and 1×10²² (cm³). The corresponding implantation dose ranges between 1×10¹⁴ and 1×10¹⁶ (cm²). In addition, the ion implantation process includes a bias power ranging between 1K eV and 4K eV to provide the intended damage and etch rate variation. After performing the ion implantation process, the patterned mask layer 3007 is removed (e.g., such as by using an appropriate etchant, solvent, or ashing process).

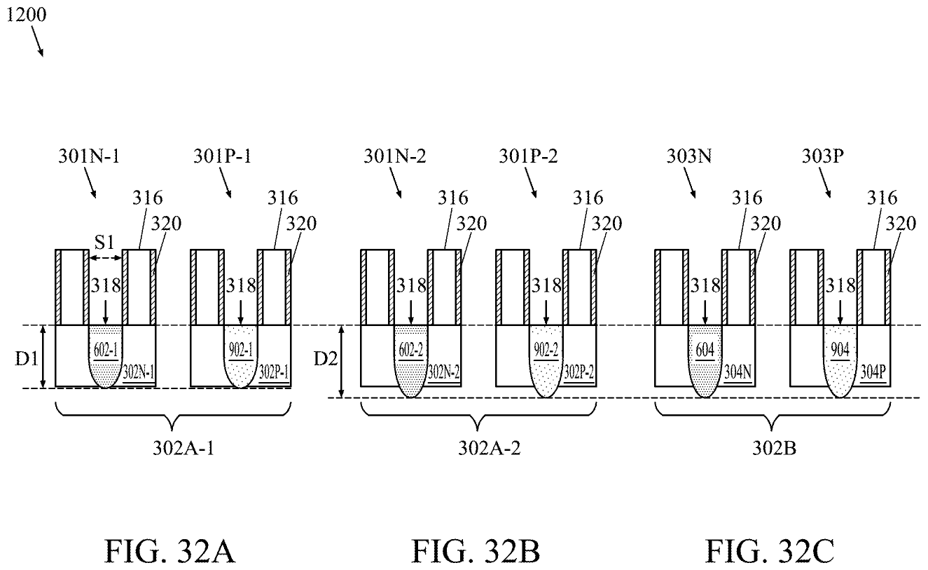

Due to the ion implantation process, and the associated increased etch rate of the source/drain region 318 of the N-type and P-type SRAM-HC devices 301N-2, 301P-2 and the N-type and P-type SOC logic devices 303N, 303P, each of the source/drain recesses of the N-type and P-type SRAM-HC devices 301N-2, 301P-2 and the N-type and P-type SOC logic devices 303N, 303P is etched to the deeper depth D2, described above. Thus, the depth D2 of the source/drain recesses of the N-type and P-type SRAM-HC devices 301N-2, 301P-2 and the N-type and P-type SOC logic devices 303N, 303P will be greater than (deeper than) the depth D1 of the source/drain recesses of the N-type and P-type SRAM-HD devices 301N-1, 301P-1. By way of example, FIGS. 32A/32B/32C illustrate a final structure of the device 1200 fabricated according to the method 2900. As shown, both the N-type SRAM devices (N-type SRAM-HD device 301N-1 and N-type SRAM-HC device 301N-2) and the P-type SRAM devices (P-type SRAM-HD device 301P-1 and P-type SRAM-HC device 301P-2) have different depths D1, D2 of their respective source/drain features (e.g., 602-1 vs. 602-2 and 902-1 vs. 902-2). In at least some embodiments, for example where the dopant species is implanted into only one of the N-type SRAM-HC device 301N-2 and the P-type SRAM-HC device 301P-2, only one of the N-type SRAM devices (N-type SRAM-HD device 301N-1 or N-type SRAM-HC device 301N-2) and one of the P-type SRAM devices (P-type SRAM-HD device 301P-1 or P-type SRAM-HC device 301P-2) will have different depths D1, D2 of their respective source/drain features (e.g., 602-1 vs. 602-2 or 902-1 vs. 902-2). Also, in the illustrated example, the N-type and P-type SRAM-HC devices 301N-2, 301P-2 and the N-type and P-type SOC logic devices 303N, 303P have the same depth D2 of the source/drain features 602-2, 902-2, 604, 904.

It is also noted that in some cases, the source/drain features 602-2 formed on adjacent fins 302N-2 of the N-type SRAM-HC device 301N-2 may merge together (e.g., during epitaxial growth), similar to the example discussed above with reference to FIG. 10B. Further, the source/drain features 902-2 formed on adjacent fins 302P-2 of the P-type SRAM-HC device 301P-2 may remain as single, non-merged epitaxial features, similar to the example discussed above with reference to FIG. 10A. In addition, if the N-type SRAM-HC device 301N-2 or the P-type SRAM-HC device 301P-2 each only include a single fin (e.g., 302N-2, 302P-2), their respective source/drain features 602-2, 902-2 may likewise remain as single, non-merged epitaxial features. While some exemplary modifications to the method 2900 have been discussed, it will be understood that these examples are merely illustrative and not meant to be limiting. Those of skill in the art, having the benefit of the present disclosure, will understand that yet other embodiments and/or modifications are possible, without departing from the scope of this disclosure.

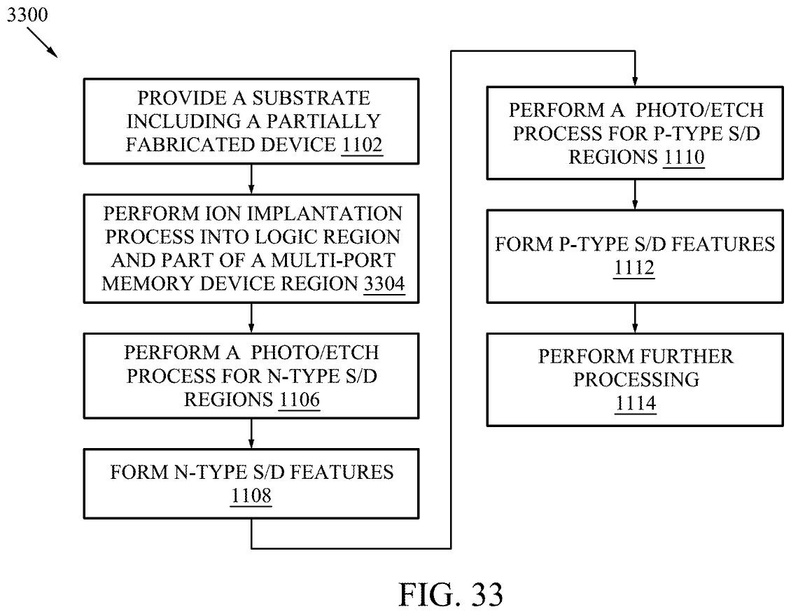

Referring to FIG. 33, illustrated therein is still another method 3300 of semiconductor fabrication including fabrication of the semiconductor device 1200, discussed above with reference to the method 1100. The method 3300 is similar to the methods 1100 and 2900, except for the ion implantation process step. Therefore, for simplicity of discussion, the steps of the method 3300 that are the same as those of the method 1100 are not repeated here. With respect to the ion implantation process, block 1104 of the method 1100 described implanting a dopant species into a logic device region (e.g., including the N-type SOC logic device 303N and the P-type SOC logic device 303P) to increase the etch rate of the source/drain regions 318 in the logic device region. In the method 3300, block 1104 is replaced with block 3304, where a dopant species is implanted into the logic device region (e.g., including the N-type SOC logic device 303N and the P-type SOC logic device 303P) and into part of a multi-port high-current SRAM (SRAM-HC) device region (e.g., which includes a first N-type SRAM-HC device 301HC-N1, a second N-type SRAM-HC device 301HC-N2, and a P-type SRAM-HC device 301HC-P) to increase the etch rate of the source/drain regions 318 in the logic device region and in part of the SRAM-HC device region. While the example below is described as implanting a dopant species into the second N-type SRAM-HC device 301HC-N2 (and not the first N-type SRAM-HC device 301HC-N1 or the P-type SRAM-HC device 301HC-P), it will be understood that in some cases, a dopant species may additionally or alternatively be implanted into one or both of the first N-type SRAM-HC device 301HC-N1 and the P-type SRAM-HC device 301HC-P.

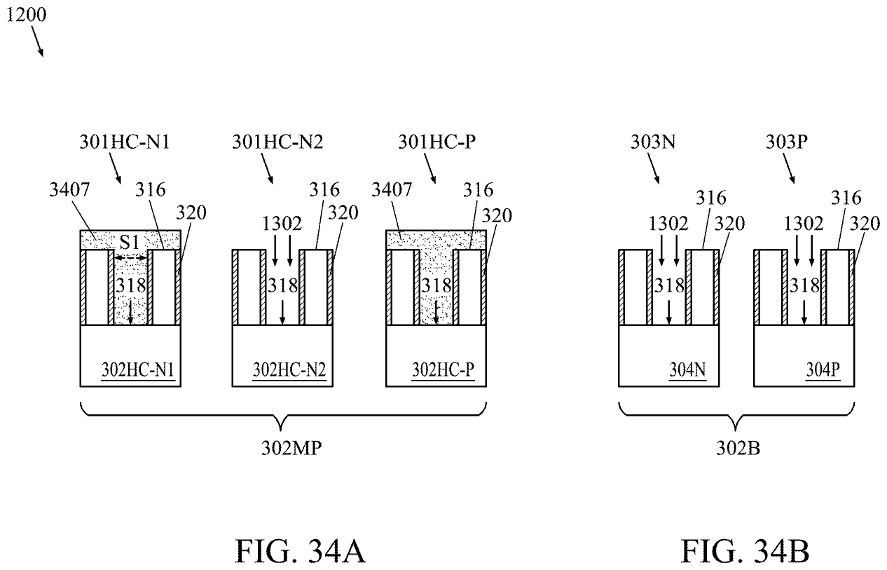

An embodiment of the block 3304 of the method 3300 is described below with reference to FIGS. 34A/34B, which provide cross-sectional views of embodiments of the device 1200 along a plane substantially parallel to a plane defined by section AA′ of FIG. 1. As shown in FIGS. 34A/34B, an ion implantation process is performed into the source/drain regions 318 of the second N-type SRAM-HC device 301HC-N2, and the N-type and P-type SOC logic devices 303N, 303P. Initially, a mask layer may be deposited and patterned to form a patterned mask layer 3407 having an opening which exposes the second N-type SRAM-HC device 301HC-N2 and the N-type and P-type SOC logic devices 303N, 303P, while the first N-type SRAM-HC device 301HC-N1 and the P-type SRAM-HC device 301HC-P remain protected by the patterned mask layer 3407. In some embodiments, the mask layer includes a resist layer and/or a hard mask layer (e.g., silicon oxide, silicon nitride, silicon oxynitride, silicon carbide, or other appropriate hard mask layer) such that the patterned mask layer 3407 may include a patterned resist layer and/or a patterned hard mask layer, as previously discussed. In some examples, and due to the smaller dimensions of the opening formed in the patterned mask layer 3407 to expose the second N-type SRAM-HC device 301HC-N2 and the N-type and P-type SOC logic devices 303N, formation of the patterned mask layer 3407 may include use of a high-grade photomask and a lithography system with high resolution, as discussed above.

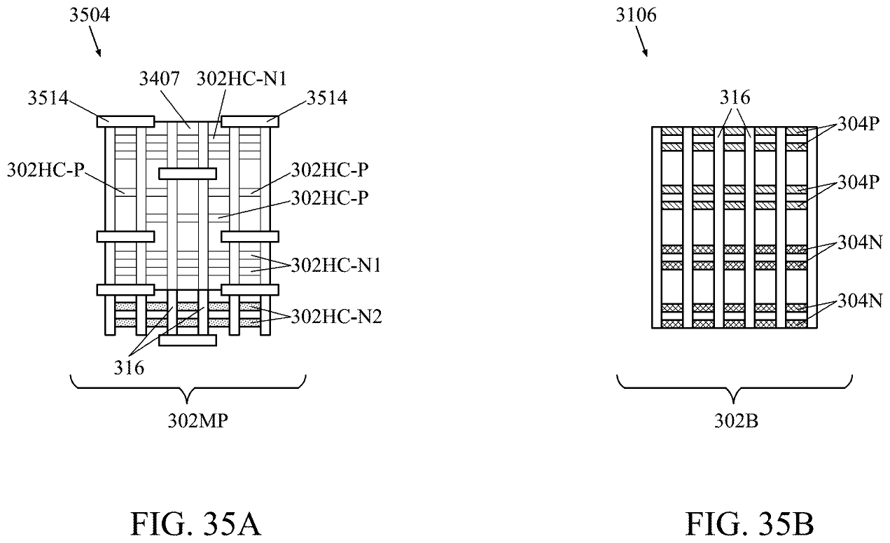

For purposes of illustration, FIGS. 35A/35B illustrate top-down views of regions 302MP and 302B of the substrate, which respectively include a multi-port SRAM HC cell (or portion thereof) 3504 and the SOC logic cell (or portion thereof) 3106 after formation of the patterned mask layer 3407. In some embodiments, the multi-port SRAM-HC cell 3504 includes the first N-type SRAM-HC device 301HC-N1 including a plurality of N-type fins 302HC-N1, the second N-type SRAM-HC device 301HC-N2 including a plurality of N-type fins 302HC-N2, and the P-type SRAM-HC device 301HC-P including a plurality of P-type fins 302HC-P. The P-type SRAM-HC devices 301HC-P may form a pull-up region of the SRAM HC cell 3504, the first N-type SRAM-HC devices 301HC-N1 may form a pull-down/pass-gate region of the SRAM HC cell 3504, and the second N-type SRAM-HC devices 301HC-N2 may form a read-port or read-port region of the SRAM HC cell 3504. The SOC logic cell 3106, as discussed above, is composed of the N-type SOC logic devices 303N including a plurality of N-type fins 304N and P-type SOC logic devices 303P including a plurality of P-type fins 304P. Each of the SRAM-HC cell 3504 and the SOC logic cell 3106 also illustrate the gate stacks 316 formed over respective fins 302HC-N1, 302HC-N2, 302HC-P, 304N, 304P within each of the regions 302MP, 302B. The top-down views of the region 302MP also illustrates cut gate isolation regions 3514, which define regions where the gate stacks 316 are cut to form multiple, adjacent gate stacks 316 that are electrically isolated from each other by a dielectric layer formed in the cut gate isolation regions 3514. As shown, the patterned mask layer 3407 exposes the second N-type SRAM-HC device 301HC-N2 including the plurality of fins 302HC-N2 and the N-type and P-type SOC logic devices 303N, 303P including the plurality of fins 304N, 304P, while the first N-type SRAM-HC device 301HC-N1 and the P-type SRAM-HC device 301HC-P including the plurality of fins 302HC-N1, 302HC-P remain protected by the patterned mask layer 3407.

Whether or not a hard mask layer is used, and after exposure of the second N-type SRAM-HC device 301HC-N2 and the N-type and P-type SOC logic devices 303N, 303P, an ion implantation process is performed to introduce a dopant species into the source/drain regions 318 of the second N-type SRAM-HC device 301HC-N2 and the N-type and P-type SOC logic devices 303N, 303P. The dopant species is introduced into the source/drain regions 318 but not into the channels (portions of the fins underlying the gate stacks 316) since the channels remain covered by the gate stacks 316. In some embodiments, the dopant species includes at least one of carbon (C), silicon (Si), germanium (Ge), hydrogen (H), nitrogen (N), fluorine (F), argon (Ar), and a combination thereof. Alternatively, or additionally, the dopant species includes at least one of gallium (Ga), phosphorous (P), arsenic (As), and a combination thereof. In some cases, the implantation process is performed at an angle that is substantially perpendicular to the substrate (e.g., at a tilt angle of about zero degrees), although other implant angles are possible. In some embodiments, the ion implantation process is performed through the portion of the one or more spacer layers 320 or the separately formed dielectric layer, if present, between the gate stacks 316 and over the source/drain regions 318. The purpose of implanting the dopant species into the source/drain regions 318 is to modify the etch rate of the source/drain regions 318 during a subsequent etching process to recess the source/drain regions 318 (blocks 1106 and 1110). In the present example, the etch rate of the implanted source/drain regions 318 of the second N-type SRAM-HC device 301HC-N2 and the N-type and P-type SOC logic devices 303N, 303P is increased. In some cases, the increased etch rate is due to damage to the source/drain regions 318 caused by the implanted dopant ions, which cause structural changes (e.g., such as defect formation) and accordingly increase the etch rate of the implanted regions. In some embodiments, the doping concentration of the implanted dopant species ranges between 1×10¹⁹ and 1×10²² (cm³). The corresponding implantation dose ranges between 1×10¹⁴ and 1×10¹⁶ (cm²). In addition, the ion implantation process includes a bias power ranging between 1K eV and 4K eV to provide the intended damage and etch rate variation. After performing the ion implantation process, the patterned mask layer 3407 is removed (e.g., such as by using an appropriate etchant, solvent, or ashing process).

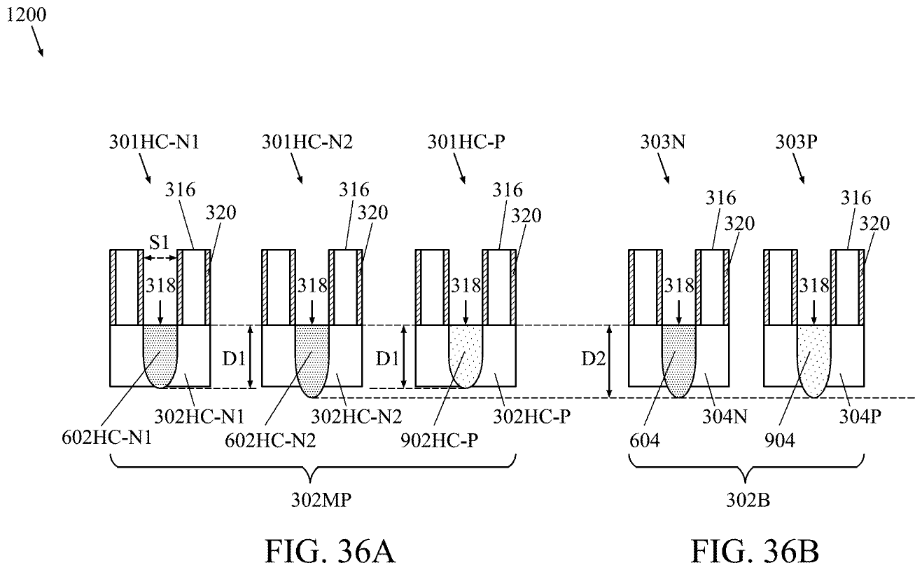

Due to the ion implantation process, and the associated increased etch rate of the source/drain region 318 of the second N-type SRAM-HC device 301HC-N2 and the N-type and P-type SOC logic devices 303N, 303P, each of the source/drain recesses of the second N-type SRAM-HC device 301HC-N2 and the N-type and P-type SOC logic devices 303N, 303P is etched to the deeper depth D2, described above. Thus, the depth D2 of the source/drain recesses of the second N-type SRAM-HC device 301HC-N2 and the N-type and P-type SOC logic devices 303N, 303P will be greater than (deeper than) the depth D1 of the source/drain recesses of the first N-type SRAM-HC device 301HC-N1 and the P-type SRAM-HC device 301HC-P. By way of example, FIGS. 36A/36B illustrate a final structure of the device 1200 fabricated according to the method 3300. As shown, the source/drain feature 602HC-N2 of the second N-type SRAM-HC device 301HC-N2 has a different depth D2 as compared to the depth D1 of the source/drain features 602HC-N1, 902HC-P of the first N-type SRAM-HC device 301HC-N1 and the P-type SRAM-HC device 301HC-P. In at least some embodiments, for example where the dopant species is additionally or alternatively implanted into one or both of the first N-type SRAM-HC device 301HC-N1 and the P-type SRAM-HC device 301HC-P, various ones of the source/drain features 602HC-N1, 602HC-N2, 902HC-P may have the same depth or different depths. Also, in the illustrated example, the second N-type SRAM-HC device 301HC-N2 and the N-type and P-type SOC logic devices 303N, 303P have the same depth D2 of the source/drain features 602HC-N2, 604, 904.

It is also noted that in various embodiments, one or both of the source/drain features 602HC-N1 formed on adjacent fins 302HC-N1 of the first N-type SRAM-HC device 301HC-N1 and the source/drain features 602HC-N2 formed on adjacent fins 302HC-N2 of the second N-type SRAM-HC device 301HC-N2 may merge together (e.g., during epitaxial growth), similar to the example discussed above with reference to FIG. 10B. Further, the source/drain features 902HC-P formed on adjacent fins 302HC-P of the P-type SRAM-HC device 301HC-P may remain as single, non-merged epitaxial features, similar to the example discussed above with reference to FIG. 10A. In addition, if the first N-type SRAM-HC device 301HC-N1 or the second N-type SRAM-HC device 301HC-N2 each only include a single fin (e.g., 302HC-N1, 302HC-N2), their respective source/drain features 602HC-N1, 602HC-N2 may likewise remain as single, non-merged epitaxial features. While some exemplary modifications to the method 3300 have been discussed, it will be understood that these examples are merely illustrative and not meant to be limiting. Those of skill in the art, having the benefit of the present disclosure, will understand that yet other embodiments and/or modifications are possible, without departing from the scope of this disclosure.

Thus, the various embodiments described herein offer several advantages over the existing art. It will be understood that not all advantages have been necessarily discussed herein, no particular advantage is required for all embodiments, and other embodiments may offer different advantages. For example, embodiments discussed herein include structures and methods for the co-optimization of SOC logic devices and SRAM devices. In various embodiments, a semiconductor device may include individual device structures to simultaneously meet the performance and design requirements of each of the SOC logic devices and SRAM devices. As an example, and in accordance with the disclosed embodiments, intentionally different source/drain depths for logic devices (e.g., SOC logic devices) and SRAM devices are provided. In some embodiments, the source/drain depth for SRAM devices may be shallower than the source/drain depth for SOC logic devices, for example, to provide tighter control of SCEs. In some embodiments, formation of the intentionally different source/drain depths may be accomplished by (i) a 2-step or multi-step S/D recess process using a high-grade photomask (e.g., such as EUV), or by (ii) an implantation-enhanced S/D recess process using at least one low-grade photomask. The implantation-enhanced S/D recess process may be accomplished at a reduced cost using simplified lithography, for example, as compared to the 2-step or multi-step S/D recess process. After the S/D recess process, an epitaxial S/D growth process is performed (e.g., in N-type and P-type regions of both SOC logic devices and SRAM devices) to form respective epitaxial S/D features having different source/drain depths. Regardless of the approach used, embodiments of the present disclosure provide independent optimization of S/D depth for N-type and P-type SOC logic device and SRAM devices. Additional embodiments and advantages are discussed below and/or will be evident to those skilled in the art in possession of this disclosure.

Thus, one of the embodiments of the present disclosure described a method that includes performing an ion implantation process into a first device region of a substrate. In some embodiments, the method further includes performing a first photolithography and etch process to simultaneously form a first source/drain recess for a first device in the first device region and a second source/drain recess for a second device in a second device region different than the first device region. In various examples, a first depth of the first source/drain recess is greater than a second depth of the second source/drain recess.

In another of the embodiments, discussed is a method that includes performing an ion implantation process into a memory device region or a logic device region to modify an etch rate of one of a first source/drain region within the memory device region or a second source/drain region within the logic device region. In some embodiments, the method further includes simultaneously etching the first source/drain region to form a first source/drain recess for a first memory device and the second source/drain region to form a second source/drain recess for a first logic device. In some examples, the method further includes forming a first source/drain feature within the first source/drain recess and a second source/drain feature within the second source/drain recess. In various embodiments, a first depth of the first source/drain feature is different than a second depth of the second source/drain feature.

In yet another of the embodiments, discussed is a semiconductor device having a substrate including a first device region and a second device region. In some embodiments, the semiconductor device further includes a first gate structure disposed in the first device region and a second gate structure disposed in the second device region. In some examples, the semiconductor device further includes a first source/drain feature disposed adjacent to the first gate structure and a second source/drain feature disposed adjacent to the second gate structure. In some cases, a first top surface of the first source/drain feature and a second top surface of the second source/drain feature are substantially level. In some embodiments, a first bottom surface of the first source/drain feature is a first distance away from the first top surface, and a second bottom surface of the second source/drain feature is a second distance away from the second top surface. In some cases, the second distance is greater than the first distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
performing an ion implantation process into a first device region of a substrate; and
performing a first photolithography and etch process to simultaneously form a first source/drain recess for a first device in the first device region and a second source/drain recess for a second device in a second device region different than the first device region;
wherein a first depth of the first source/drain recess is greater than a second depth of the second source/drain recess.

2. The method of claim 1, further comprising forming a first source/drain feature within the first source/drain recess and a second source/drain feature within the second source/drain recess.

3. The method of claim 1, wherein the ion implantation process increases an etch rate of a first source/drain region of the first device.

4. The method of claim 1, wherein the first device includes an N-type system-on-a-chip (SOC) logic device or a P-type SOC logic device, and wherein the second device includes an N-type static random-access memory (SRAM) device or a P-type SRAM device.

5. The method of claim 2, wherein the first source/drain feature extends above a first top surface of a first fin over which the first source/drain feature is formed, and wherein the second source/drain feature extends above a second top surface of a second fin over which the second source/drain feature is formed.

6. The method of claim 1, further comprising:
performing a second photolithography and etch process to simultaneously form a third source/drain recess for a third device in the first device region and a fourth source/drain recess for a fourth device in the second device region;
wherein a third depth of the third source/drain recess is greater than a fourth depth of the fourth source/drain recess.

7. The method of claim 1, wherein the ion implantation process includes performing a plurality of ion implantation processes at different implant angles, and wherein a first width of the first source/drain recess is greater than a second width of the second source/drain recess.

8. The method of claim 1, wherein the ion implantation process further includes performing the ion implantation process into a portion of the second device region, wherein the first photolithography and etch process simultaneously forms the first source/drain recess, the second source/drain recess, and a third source/drain recess for a third device in the portion of the second device region.

9. The method of claim 8, wherein a third depth of the third source/drain recess is both greater than the second depth of the second source/drain recess and substantially equal to the first depth of the first source/drain recess.

10. A method, comprising:
performing an ion implantation process into a memory device region or a logic device region to modify an etch rate of one of a first source/drain region within the memory device region or a second source/drain region within the logic device region; and
simultaneously etching the first source/drain region to form a first source/drain recess for a first memory device and the second source/drain region to form a second source/drain recess for a first logic device; and
forming a first source/drain feature within the first source/drain recess and a second source/drain feature within the second source/drain recess;
wherein a first depth of the first source/drain feature is different than a second depth of the second source/drain feature.

11. The method of claim 10, wherein the ion implantation process is performed into the memory device region, and wherein the etch rate of the first source/drain region is decreased.

12. The method of claim 10, wherein the ion implantation process is performed into the logic device region, and wherein the etch rate of the second source/drain region is increased.

13. The method of claim 10, wherein the first depth of the first source/drain feature is less than the second depth of the second source/drain feature.

14. The method of claim 10, wherein the ion implantation process includes performing a plurality of ion implantation processes at different implant angles, and wherein a first width of the first source/drain feature is different than a second width of the second source/drain feature.

15. The method of claim 10, wherein the first memory device includes an N-type static random-access memory (SRAM) device or a P-type SRAM device, and wherein the first logic device includes an N-type system-on-a-chip (SOC) logic device or a P-type SOC logic device.

16. A semiconductor device, comprising:
a substrate including a first device region and a second device region;
a first gate structure disposed in the first device region and a second gate structure disposed in the second device region; and
a first source/drain feature disposed adjacent to the first gate structure and a second source/drain feature disposed adjacent to the second gate structure;
wherein a first top surface of the first source/drain feature and a second top surface of the second source/drain feature are substantially level;
wherein a first bottom surface of the first source/drain feature is a first distance away from the first top surface; and
wherein a second bottom surface of the second source/drain feature is a second distance away from the second top surface, the second distance greater than the first distance.

17. The semiconductor device of claim 16, wherein the first device region includes a static random-access memory (SRAM) device region, and wherein the second device region includes a system-on-a-chip (SOC) logic device region.

18. The semiconductor device of claim 16, wherein the first source/drain feature and the second source/drain feature include an N-type source/drain feature or a P-type source/drain feature.

19. The semiconductor device of claim 16, wherein a first width of the first source/drain feature is less than a second width of the second source/drain feature.

20. The semiconductor device of claim 16, further comprising:
a third source/drain feature disposed adjacent to a third gate structure in the first device region;
wherein a third top surface of the third source/drain feature is substantially level with the first top surface and the second top surface; and
wherein a third bottom surface of the third source/drain feature is the second distance away from the third top surface.
